(19) United States
(12) Patent Application Publication
(10) Pub. No.: US 2025/0098478 A1
(43) Pub. Date: Mar. 20, 2025

(54) DISPLAY DEVICE AND METHOD OF MANUFACTURING THE DISPLAY DEVICE

(71) Applicant: Samsung Display Co., LTD., Yongin-si, (KR)

(72) Inventors: HYUNEOK SHIN, Yongin-si (KR); JUHYUN LEE, Yongin-si (KR); YUNG BIN CHUNG, Yongin-si (KR)

(21) Appl. No.: 18/790,855

(22) Filed: Jul. 31, 2024

(30) Foreign Application Priority Data
Sep. 19, 2023 (KR) 10-2023-0124826

(51) Int. Cl. H10K 59/80; H10K 59/12; H10K 59/122

(52) U.S. Cl. CPC H10K 59/80517; H10K 59/1201; H10K 59/122

(57) ABSTRACT

A display device includes a pixel defining film disposed on a circuit element layer, where a light-emitting opening is defined in the pixel defining film, a light-emitting element including a first electrode including an upper surface exposed through the light-emitting opening, where the first electrode at least partially overlaps the pixel defining film, a second electrode disposed on the first electrode. The display device includes a protective layer disposed between the first electrode and the pixel defining film. The first electrode includes a first sub-electrode including a reflective metal material, a second sub-electrode disposed on the first sub-electrode and including a transparent conductive oxide, and an intermediate layer disposed directly between the first sub-electrode and the second sub-electrode and including a tungsten oxide. The display device has high-resolution display quality and low driving voltage characteristics.

This application claims priority to Korean Patent Application No. 10-2023-0124826, filed on Sep. 19, 2023, and all the benefits accruing therefrom under 35 U.S.C. § 119, the content of which in its entirety is herein incorporated by reference.

### BACKGROUND

### Field

The present disclosure herein relates to a display device and a method of manufacturing the display device, and more particularly, to a display device including a light-emitting element having a multi-layered electrode and a method of manufacturing the display device.

### Description of the Related Art

Various display devices, which may be used for multimedia electronic devices such as, for example, a television, a mobile phone, a tablet computer, a navigation system, a game console, and a wearable device, are being developed. Such display devices may include a display panel configured to display an image. The display panel may use a so-called self-luminous display element that realizes a display by emitting light from a light-emitting material including an organic compound, a quantum dot, or the like in a light-emitting layer disposed between electrodes facing each other.

In some aspects, with the recent increasing demand for high-definition and portability of multi-media electronic devices, there is a need for a display panel which is reduced in size and capable of providing excellent high-resolution display quality.

### SUMMARY

The present disclosure provides a high-resolution display device having a low driving voltage and excellent display quality.

The present disclosure also provides a method of manufacturing a display device having excellent high-resolution display quality by having a first electrode structure that may be patterned in a single etching process operation and a protective layer structure that protects the first electrode during patterning.

An embodiment supported by aspects of the present disclosure provides a display device including: a circuit element layer; a pixel defining film disposed on the circuit element layer, where a light-emitting opening is defined in the pixel defining film; a light-emitting element including a first electrode including an upper surface exposed through the light-emitting opening, where the first electrode at least partially overlaps the pixel defining film, a second electrode disposed on the first electrode, and a functional layer disposed between the first electrode and the second electrode; and a protective layer disposed between the first electrode overlapping the pixel defining film and the pixel defining film, where the first electrode includes: a first sub-electrode including a reflective metal material; a second sub-electrode disposed on the first sub-electrode and including a transparent conductive oxide; and an intermediate layer disposed directly between the first sub-electrode and the second sub-electrode and including a tungsten oxide.

In an embodiment, an edge of the protective layer exposed through the light-emitting opening may be more recessed toward an inside of the pixel defining film than an edge of an adjacent pixel defining film.

In an embodiment, the first sub-electrode may include aluminum or an aluminum alloy.

In an embodiment, the second sub-electrode may include a polycrystalline indium tin oxide (ITO).

In an embodiment, the protective layer may be formed of an amorphous transparent conductive oxide film.

In an embodiment, the protective layer may include at least one of indium gallium zinc oxide (IGZO), indium zinc oxide (IZO), or zinc indium tin oxide (Zn-ITO).

In an embodiment, a thickness of the intermediate layer may range from about 5 Å to about 30 Å.

In an embodiment supported by aspects of the present disclosure, a display device includes: light-emitting regions which are non-overlapping on a plane; a peripheral region disposed between the light-emitting regions; a base substrate; a circuit element layer disposed on the base substrate; a pixel defining film disposed on the circuit element layer, where light-emitting openings defined in the pixel defining film correspond to the light-emitting regions; a light-emitting element including a first electrode at least partially overlapping the pixel defining film and disposed on the circuit element layer, a second electrode facing the first electrode, and a functional layer disposed between the first electrode and the second electrode; and a protective layer disposed directly between the first electrode and the pixel defining film, where the protective layer corresponds to the peripheral region and is formed of an amorphous transparent conductive oxide film.

In an embodiment, the first electrode may include: a first sub-electrode including a reflective metal material; a second sub-electrode disposed on the first sub-electrode and including a transparent conductive oxide; and an intermediate layer disposed directly between the first sub-electrode and the second sub-electrode and including a tungsten oxide.

In an embodiment, the first sub-electrode may include aluminum or an aluminum alloy, and the second sub-electrode may include a polycrystalline indium tin oxide (ITO).

In an embodiment, a thickness of the first sub-electrode may range from about 600 Å to about 1000 Å, a thickness of the second sub-electrode may range from about 20 Å to about 100 Å, and a thickness of the intermediate layer may range from about 5 Å to about 30 Å.

In an embodiment, the first electrode, the protective layer, and the pixel defining film may overlap each other in the peripheral region, and the protective layer and the pixel defining film may not overlap the first electrode in the light-emitting regions.

In an embodiment, the base substrate may include a silicon substrate.

In another embodiment supported by aspects of the present disclosure, a method for manufacturing a display device includes: sequentially providing a preliminary first sub-electrode, a preliminary intermediate layer, a preliminary second sub-electrode, and a preliminary protective layer on a circuit element layer; patterning the preliminary protective layer by removing a portion of the preliminary protective layer; forming a first electrode, in which a first sub-electrode, an intermediate layer, and a second sub-electrode are stacked, by etching portions of the preliminary first sub-electrode, the preliminary intermediate layer, and the preliminary second sub-electrode which overlap a region from which the portion of the preliminary protective layer is removed; providing a preliminary pixel defining film layer on the formed first electrode; forming a pixel defining film by patterning the preliminary pixel defining film layer, where a light-emitting opening is defined in the pixel defining film; and forming a protective layer by removing a portion of the preliminary protective layer exposed through the light-emitting opening, where an edge of the protective layer exposed through the light-emitting opening is more recessed toward the inside of the pixel defining film than an edge of the pixel defining film.

In an embodiment, the patterning of the preliminary protective layer by removing a portion of the preliminary protective layer may include forming a photosensitive pattern on the preliminary protective layer; and removing a portion of the preliminary protective layer that does not overlap the photosensitive pattern by wet etching the preliminary protective layer, where the wet etching includes providing an etching solution on the preliminary protective layer.

In an embodiment, the forming of the first electrode may include dry etching the preliminary first sub-electrode, the preliminary intermediate layer, and the preliminary second sub-electrode in a same process step.

In an embodiment, the forming of the pixel defining film may include forming a photosensitive pattern on the preliminary pixel defining film layer; and removing the preliminary pixel defining film layer by dry etching the preliminary pixel defining film layer such that an upper surface of the preliminary protective layer non-overlapping the photosensitive pattern is exposed.

In an embodiment, the forming of the protective layer may include removing the portion of the preliminary protective layer exposed through the light-emitting opening by wet etching such that an upper surface of the second sub-electrode is exposed, where the wet etching includes providing an etching solution on the preliminary protective layer.

In an embodiment, the preliminary first sub-electrode may include aluminum or an aluminum alloy, the preliminary second sub-electrode may include a polycrystalline indium tin oxide (ITO), and the preliminary intermediate layer may include a tungsten oxide.

In an embodiment, the preliminary protective layer may include an amorphous transparent conductive oxide film.

### BRIEF DESCRIPTION OF THE DRAWINGS

The accompanying drawings are included to provide a further understanding of the present disclosure, and are incorporated in and constitute a part of this specification. The drawings illustrate embodiments supported by aspects of the present disclosure and, together with the description, serve to explain principles supported by aspects of the present disclosure. In the drawings:

FIG. 1A is a perspective view of an electronic device according to an embodiment supported by aspects of the present disclosure;

FIG. 1B is an exploded perspective view of the electronic device according to an embodiment supported by aspects of the present disclosure;

FIG. 2A is a perspective view of an electronic device according to an embodiment supported by aspects of the present disclosure;

FIG. 2B is an exploded perspective view of the electronic device according to an embodiment supported by aspects of the present disclosure;

FIG. 3 is a plan view of a display device according to an embodiment supported by aspects of the present disclosure;

FIG. 4 is a plan view of a portion of the display device according to an embodiment supported by aspects of the present disclosure;

FIG. 5 is a cross-sectional view of a portion of the display device according to an embodiment supported by aspects of the present disclosure;

FIG. 6 is a cross-sectional view of a portion of the display device according to an embodiment supported by aspects of the present disclosure;

FIG. 7 is a cross-sectional view of a portion of a display panel according to an embodiment supported by aspects of the present disclosure;

FIG. 8A is a cross-sectional view of a light-emitting element according to an embodiment supported by aspects of the present disclosure;

FIG. 8B is a cross-sectional view of a light-emitting element according to an embodiment supported by aspects of the present disclosure;

FIG. 9A is a cross-sectional view illustrating a portion of the display panel corresponding to a region AA of FIG. 7;

FIG. 9B is a cross-sectional view illustrating a portion of the display panel corresponding to a region BB of FIG. 7;

FIG. 10 is a graph illustrating reflection characteristics by wavelength;

FIG. 11 is a cross-sectional view of a portion of a display panel according to an embodiment supported by aspects of the present disclosure; and

FIGS. 12A to 12G illustrate example operations of a method of manufacturing a display device according to an embodiment supported by aspects of the present disclosure.

### DETAILED DESCRIPTION

In the present specification, various modifications can be made, various forms can be used, and example embodiments will be illustrated in the drawings and described in detail in the text. However, this is not intended to limit the example embodiments to a specific form disclosed, and it will be understood that all changes, equivalents, or substitutes which fall in the spirit and technical scope of the embodiments supported by the present disclosure should be included.

In this specification, it will be understood that when an element (or region, layer, portion, part, or the like) is referred to as being “on”, “connected to” or “coupled to” another element, it can be directly on, connected or coupled to the other element, or intervening elements may be present.

Like reference numerals refer to like elements throughout. In some aspects, in the drawings, the thicknesses, ratios, and dimensions of elements are exaggerated for effective description of the technical contents. As used herein, the term “and/or” includes any and all combinations that the associated configurations can define.

It will be understood that, although the terms first, second, and the like may be used herein to describe various elements, these elements should not be limited by these terms. These terms are only used to distinguish one element from another element. For example, a first element could be termed a second element without departing from the scope of the embodiments of the present disclosure. Similarly, the second element may also be referred to as the first element. The terms of a singular form include plural forms unless otherwise specified.

In some aspects, terms, such as “below”, “lower”, “above”, “upper” and the like, are used herein for ease of description to describe one element's relation to another element(s) as illustrated in the figures. The above terms are relative concepts and are described based on the directions indicated in the drawings.

It will be understood that the terms “include” and/or “have”, when used in this specification, specify the presence of stated features, integers, steps, operations, elements, components and/or groups thereof, but do not preclude the presence or addition of one or more other features, integers, steps, operations, elements, components, and/or groups thereof.

In the present application, being “directly disposed” may mean that there is no layer, film, region, plate, or the like added between a part such as, for example, a layer, film, region, or plate and another part such as, for example, a layer, film, region, or plate. For example, being “directly disposed” may mean that no additional member such as, for example, an adhesive member is disposed between two layers or two members.

The terms “about” or “approximately” as used herein are inclusive of the stated value and include a suitable range of deviation for the particular value as determined by one of ordinary skill in the art, considering the measurement in question and the error associated with measurement of the particular quantity. The term “about” can mean within one or more standard deviations, or within ±30%, 20%, 10%, 5% of the stated value, for example.

The term “substantially,” as used herein, means approximately or actually. The term “substantially equal” means approximately or actually equal. The term “substantially the same” means approximately or actually the same. The term “substantially perpendicular” means approximately or actually perpendicular.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, a display device according to an embodiment supported by aspects of the present disclosure and a method of manufacturing the display device according to an embodiment supported by aspects of the present disclosure will be described with reference to the accompanying drawings.

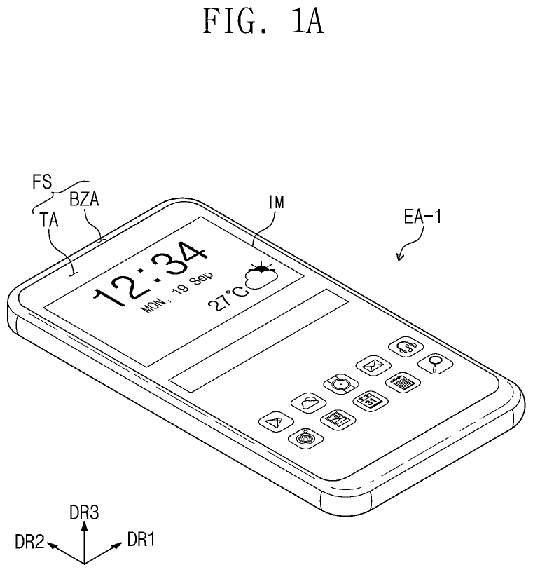

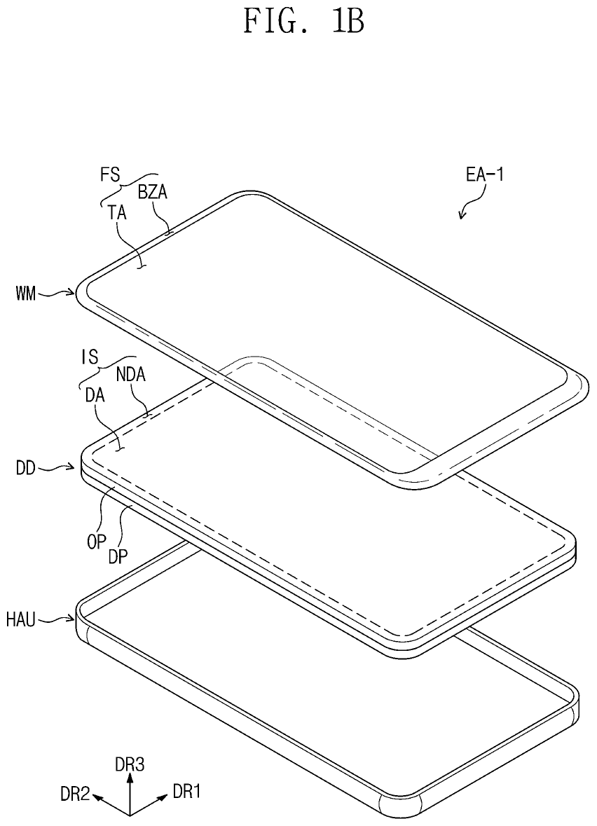

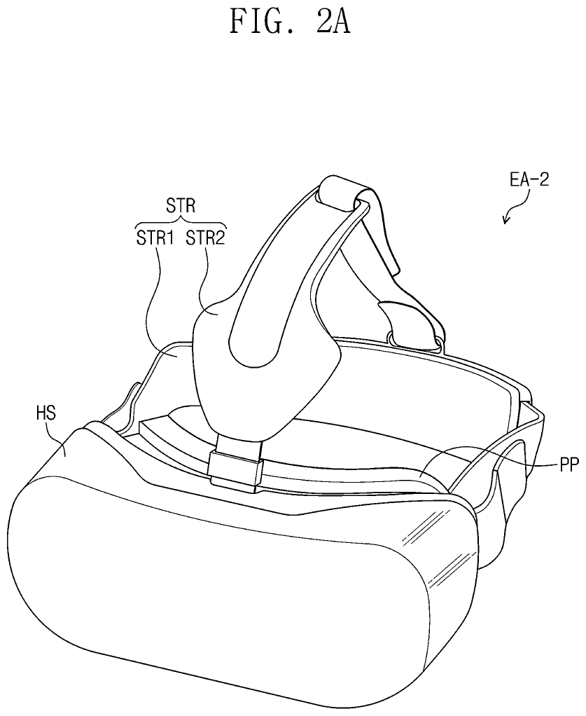

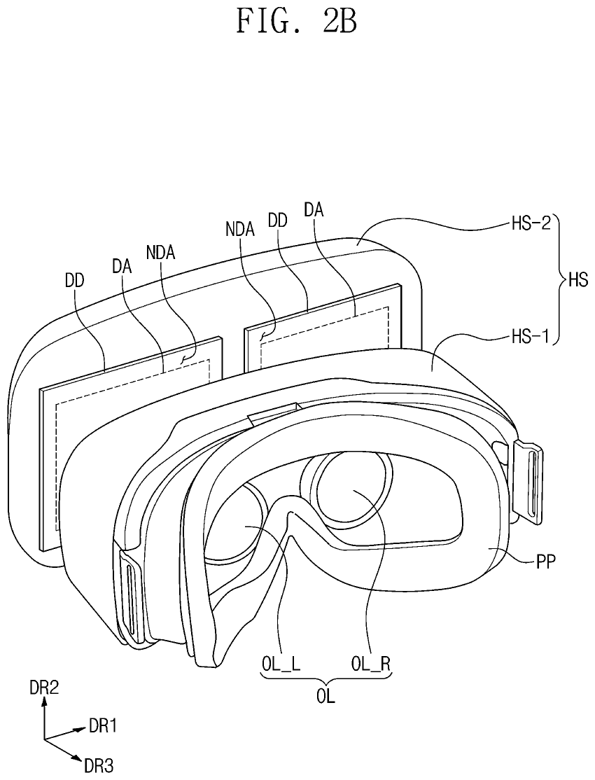

FIG. 1A is a perspective view of an electronic device according to an embodiment supported by aspects of the present disclosure. FIG. 1B is an exploded perspective view of the electronic device according to an embodiment supported by aspects of the present disclosure. FIG. 2A is a perspective view of an electronic device according to an embodiment supported by aspects of the present disclosure, and FIG. 2B is an exploded perspective view of the electronic device according to an embodiment supported by aspects of the present disclosure.

An electronic device according to an embodiment supported by aspects of the present disclosure may be activated according to an electrical signal and display an image. For example, examples of the electronic device may include small and medium-sized devices such as, for example, a monitor, a laptop computer, a personal digital terminal, a car navigation unit, a game console, a smartphone, a tablet, and a camera as well as large devices such as, for example, a television and an external billboard. However, these are presented as examples and are not limited to any one embodiment as long as they do not depart from the concept of the embodiments supported by the present disclosure.

FIGS. 1A and 1B illustrate examples in which an electronic device EA-1 according to an embodiment supported by aspects of the present disclosure is a smart phone. In some aspects, FIGS. 2A and 2B illustrate examples in which an electronic device EA-2 according to an embodiment supported by aspects of the present disclosure is a wearable display device.

The electronic devices EA-1 and EA-2 according to an embodiment supported by aspects of the present disclosure may be rigid or flexible. The term “flexible” refers to the property of being bendable. For example, the flexible electronic devices EA-1 and EA-2 may include a curved device, a rollable device, or a foldable device.

In some embodiments, FIG. 1A and the following drawings illustrate first to third direction axes DR1 to DR3, and directions indicated by the first to third direction axes DR1, DR2, and DR3 described herein are relative concepts and may be converted into other directions. In some aspects, the directions indicated by the first to third direction axes DR1, DR2, and DR3 may be described as first to third directions for which the same reference numerals may be used. In this specification, the first direction axis DR1 and the second direction axis DR2 may be orthogonal to each other, and the third direction axis DR3 may be a normal direction with respect to a plane defined by the first direction axis DR1 and the second direction axis DR2.

The thickness direction of the electronic device EA-1 according to an embodiment supported by aspects of the present disclosure, which is illustrated in FIGS. 1A and 1B, may be parallel to the third direction axis DR3 which is the normal direction with respect to the plane defined by the first and second directions axes DR1 and DR2. In this specification, the front (or upper) and rear (or lower) surfaces of members constituting the electronic device EA-1 may be defined based on the third direction axis DR3. The front (or upper) and rear (or lower) surfaces of each member constituting the electronic device EA-1 may be opposed to each other in the third direction DR3, and the normal direction of each of the front and rear surfaces may be substantially parallel to the third direction DR3. A separation distance between the front and rear surfaces defined along the third direction DR3 may correspond to the thickness of a member.

In this specification, the expression “on a plane” may be defined as viewed in the third direction DR3. In this specification, the expression “on a cross section” may be defined as viewed in the first direction DR1 or the second direction DR2. In some embodiments, directions indicated by the first to third directions DR1, DR2, and DR3 are relative concepts and may be converted into other directions.

Referring to FIGS. 1A and 1B, the electronic device EA-1 according to an embodiment supported by aspects of the present disclosure may display an image IM through a display surface FS. The image IM may include a still image as well as a dynamic image. FIG. 1A illustrates a watch window and icons as an example of the image IM. The display surface FS on which the image IM is displayed may correspond to the front surface of the electronic device EA-1.

Referring to FIG. 1B, the electronic device EA-1 according to an embodiment supported by aspects of the present disclosure may include a window module WM, a display device DD, and a housing HAU. The window module WM and the housing HAU may be coupled to each other to form the exterior of the electronic device EA-1.

The window module WM may be disposed on the display device DD and protect the display device DD from an external impact or scratches. The window module WM may cover the entire outside of the display device DD. The front surface of the window module WM may define the display surface FS of the electronic device EA-1. The display surface FS may include a transmission region TA and a bezel region BZA. The transmission region TA may be an optically transparent region. For example, the transmission region TA may have a visible light transmittance of about 90% or more.

The bezel region BZA of the window module WM may have a relatively low light transmittance, compared to the transmission region TA. The bezel region BZA may define the shape of the transmission region TA. The bezel region BZA may be adjacent to and surround the transmission region TA. However, the bezel region BZA being adjacent to and surrounding the transmission region TA is an example, and in an embodiment supported by aspects of the present disclosure, the bezel region BZA may be omitted.

In an embodiment supported by aspects of the present disclosure, the window module WM may include a base substrate including an optically transparent insulating material. The base substrate may include at least one of a glass substrate or a synthetic resin film. The base substrate may have a single-layered structure or a multi-layered structure in which a plurality of films are coupled to each other. The window module WM may include a reflection reduction layer disposed on the base substrate. For example, the reflection reduction layer may include a polarizing layer. In some aspects, the window module WM may further include a functional layer such as, for example, an anti-fingerprint layer, a phase control layer, or a hard coating layer.

The window module WM may further include an adhesive layer. The base substrate and the display device DD may be coupled to each other by an adhesive layer. Without being limited thereto, however, the adhesive layer may be omitted, and the window module WM may be disposed directly on the display device DD.

The display device DD may be disposed below the window module WM. The display device DD may be configured to substantially generate an image IM. The image IM generated by the display device DD is displayed on the display surface IS of the display device DD and may be visually recognized by a user from the outside through the transmission region TA.

The display device DD includes a display region DA and a non-display region NDA. The display region DA may be activated according to an electrical signal. The non-display region NDA is adjacent to the display region DA. The non-display region NDA may surround the display region DA. The non-display region NDA is covered by the bezel region BZA and may not be visually recognized from the outside.

The housing HAU may be coupled to the window module WM. The housing HAU may be coupled to the window module WM and provide a predetermined internal space. The display device DD may be accommodated in the internal space.

The housing HAU may include a material having relatively high rigidity. For example, the housing HAU may include a plurality of frames and/or plates formed of glass, plastic, or metal, or a combination thereof. The housing HAU may reliably protect the components of the electronic device EA-1 accommodated in the internal space from an external impact.

Referring to FIG. 1B, the display device DD according to an embodiment supported by aspects of the present disclosure may include a display panel DP and a light control panel OP. Although not separately illustrated, the electronic device EA-1 according to an embodiment supported by aspects of the present disclosure may further include a protective member disposed on the lower surface of the display panel DP or an input sensor disposed on the display panel DP. The input sensor may sense an external input, for example, by a capacitive method, an electromagnetic induction method or a pressure sensing method.

FIG. 2A is a perspective view of an electronic device EA-2 according to an embodiment supported by aspects of the present disclosure. FIG. 2B is an exploded perspective view of a portion of the electronic device EA-2 according to an embodiment supported by aspects of the present disclosure.

The electronic device EA-2 according to an embodiment supported by aspects of the present disclosure, which is illustrated in FIGS. 2A and 2B, is activated according to an electrical signal and may be a wearable device. The wearable device may be a device worn on a user's body and may include a head-mounted display (HMD) device that implements an extended Reality (XR) environment. FIGS. 2A and 2B illustrate examples in which the electronic device EA-2 is a head-mounted display device, but embodiments supported by the present disclosure are not limited thereto.

The electronic device EA-2 according to an embodiment supported by aspects of the present disclosure, which is illustrated in FIGS. 2A and 2B, is a display device worn on a user's head. The electronic device EA-2 may provide an image in a state in which the actual peripheral vision of a user is blocked. The electronic device EA-2 may support effective immersion of a user in a virtual reality environment.

The electronic device EA-2 may include a body unit HS, a strap STR, a cushion portion PP, and a display device DD. Although not illustrated, the electronic device EA-2 may include various sensors and cameras.

The body unit HS may be worn on a user's head. The display panel DP that displays an image, an acceleration sensor (not illustrated), and the like may be accommodated inside the body unit HS. The acceleration sensor may sense a user's movement and transmit a predetermined signal to the display device DD. Accordingly, the display device DD may provide an image corresponding to a change in the user's gaze. Therefore, the user may experience virtual reality similar to actual reality. As described with reference to FIG. 1B, the display device DD may include the display panel DP (see FIG. 1B) and the light control panel OP (see FIG. 1B). However, embodiments supported by the present disclosure are not limited thereto, and the configuration of the display device DD included in the electronic device EA-2 according to an embodiment supported by aspects of the present disclosure may be provided different from the example illustrated in FIG. 1B and the like in association with suiting the characteristics of a wearable device.

In the body unit HS, components having various functions besides those described herein may be accommodated. For example, a control unit (not illustrated) for adjusting volume, screen brightness, or the like may be additionally disposed outside the body unit HS. The control unit may be provided in the form of a physical button or a touch sensor. In some aspects, a proximity sensor (not illustrated) that determines whether or not a user is wearing a device may be accommodated in the body unit HS. In some aspects, an external display panel may be further disposed in the body unit HS.

The body unit HS may be separated into a body portion HS-1 and a cover portion HS-2. FIG. 2B illustrates an example of shape in which the body portion HS-1 and the cover portion HS-2 are separated from each other, but embodiments supported by the present disclosure are not limited thereto. For example, the body portion HS-1 and the cover portion HS-2 may be provided as an integral unit and may not be separated from each other.

Display devices DD may be disposed between the body portion HS-1 and the cover portion HS-2. Each of the display devices DD may provide an image through a display region DA. Each of the display devices DD may include a non-display region NDA surrounding the display region DA. In some embodiments, in an embodiment supported by aspects of the present disclosure, the non-display region NDA may be disposed on a single side of the display region DA or may be omitted.

In FIG. 2B, an example is illustrated in which a left-eye image and a right-eye image are displayed through separate display devices DD, but embodiments supported by the present disclosure are not limited thereto. For example, the left-eye image and the right-eye image may be displayed through one display device. The display devices DD may be driven by separate driving units. Without being limited thereto, however, the display devices DD may be driven by a single driving unit. The display devices DD generate images corresponding to input image data.

The strap STR may be coupled to the body unit HS such that the body unit HS can be easily worn by a user. The strap STR may include a main strap portion STR1 and an upper strap portion STR2.

The main strap portion STR1 may be worn along the head circumference of a user. The main strap portion STR1 may fix the body unit HS to the user such that the body unit HS is in close contact with the user's head. The upper strap portion STR2 may connect the body unit HS and the main strap portion STR1 to each other along the upper portion of the user's head. The upper strap portion STR2 may prevent the body unit HS from falling off. In some aspects, the upper strap portion STR2 may distribute the load of the body unit HS to further improve the user's wearing comfort.

The strap STR is not limited to the examples described herein with respect to FIG. 2A, and the strap STR may be modified into various forms supportive of fixing the body unit HS to the user. For example, in another embodiment supported by aspects of the present disclosure, the upper strap portion STR2 may be omitted. In some aspects, in another embodiment supported by aspects of the present disclosure, the strap STR may be modified into various forms, such as, for example, a helmet coupled to the body unit HS, or eyeglass temples coupled to the body unit HS.

The cushion portion PP may be disposed between the body unit HS and the user's head. The cushion portion PP may be formed of a material having a freely deformable shape. For example, the cushion portion PP may be formed of a polymer resin (e.g., polyurethane, polycarbonate, polypropylene, and polyethylene) or a sponge obtained by foaming and molding a rubber solution, a urethane-based material, or an acrylic-based material. However, embodiments supported by the present disclosure are not limited thereto.

The cushion portion PP allows the body unit HS to be in close contact with the user, thereby improving the user's wearing comfort. The cushion portion PP may be detached from the body unit HS. In another embodiment supported by aspects of the present disclosure, the cushion portion PP may be omitted.

An optical system OL may be disposed inside the body portion HS-1 of the body unit HS. The optical system OL may enlarge an image provided from the display devices DD. Each of the display devices DD may display the image in the third direction DR3 through the display region DA parallel to the first direction DR1 and the second direction DR2 crossing the first direction DR1. The optical system OL may be disposed such that the optical system OL is spaced apart from the display devices DD in the third direction DR3. The optical system OL may be disposed between the display devices DD and the user's eyes. The optical system OL may include a right-eye optical system OL_R and a left-eye optical system OL_L. The left-eye optical system OL_L may enlarge and provide an image to the left pupil of the user, and the right-eye optical system OL_R may enlarge and provide an image to the right pupil of the user.

The left-eye optical system OL_L and the right-eye optical system OL_R may be disposed spaced apart from each other in the first direction DR1. The distance between the right-eye optical system OL_R and the left-eye optical system OL_L may be adjustable based on the distance between the two eyes of the user. In some aspects, the distance between the optical system OL and the display devices DD may be adjustable according to the vision of the user.

The optical system OL may include a convex aspherical lens. For example, the optical system OL may include a pancake lens, but is not particularly limited thereto. In this embodiment, as an example, each of the left-eye optical system OL_L and the right-eye optical system OL_R is described as being composed of one lens, but embodiments supported by the present disclosure are not limited thereto. For example, each of the left-eye optical system OL_L and the right-eye optical system OL_R may include a plurality of lenses.

In some embodiments, the electronic device EA-2 according to an embodiment supported by aspects of the present disclosure, which is illustrated in FIGS. 2A and 2B, may further include a window member (not illustrated) disposed on the display device DD. The window member (not illustrated) may include a base substrate and a reflection reduction layer.

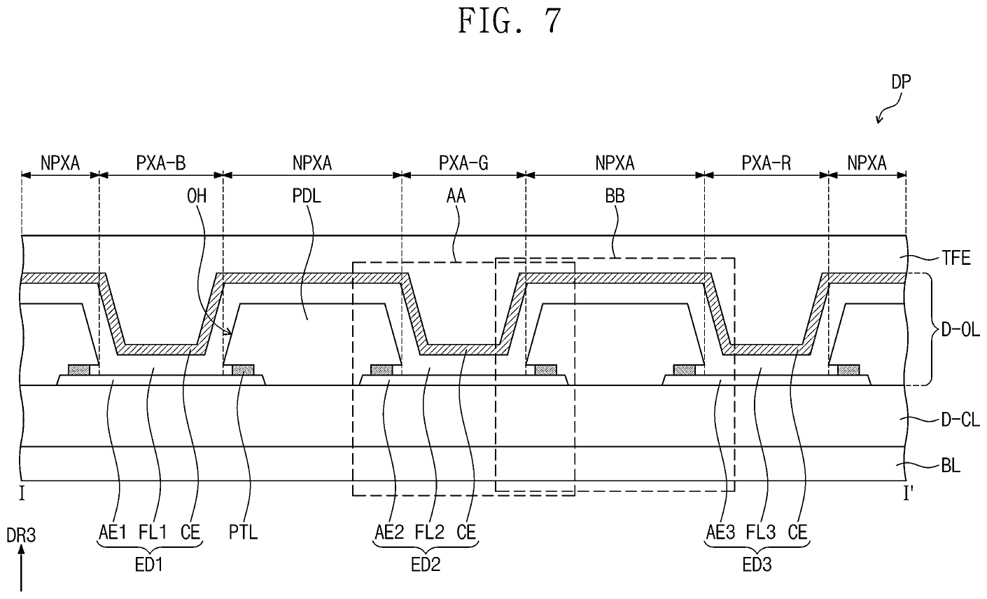

The display devices DD included in the electronic devices EA-1 and EA-2 according to an embodiment supported by aspects of the present disclosure, which are described with reference to FIGS. 1A to 2B, may include an organic light-emitting display panel, an inorganic light-emitting display panel, an organic-inorganic light-emitting display panel, a quantum dot display panel, a micro LED display panel, or a nano LED display panel. In this embodiment, the display devices DD are described as including an organic light-emitting display panel as an example, but embodiments supported by the present disclosure are not limited thereto. The display devices DD included in the electronic devices EA-1 and EA-2 according to an embodiment supported by aspects of the present disclosure may have high-resolution characteristics. For example, the display device DD according to an embodiment supported by aspects of the present disclosure may have a display quality of an ultra-high resolution of about 3000 ppi or higher. Accordingly, a pixel electrode (or a first electrode) constituting light-emitting elements ED1, ED2, and ED3 (see FIG. 7) included in the display device DD according to an embodiment supported by aspects of the present disclosure may be provided as a fine pattern having high precision.

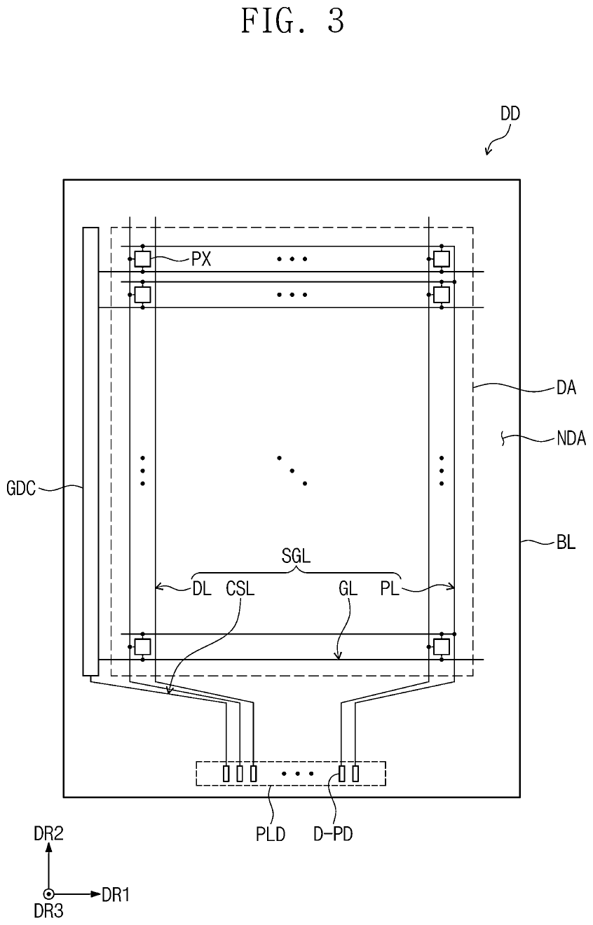

FIG. 3 is a plan view of a display device according to an embodiment supported by aspects of the present disclosure. The display device DD may include a base substrate BL divided into a display region DA and a non-display region NDA.

The display device DD may include pixels PX disposed in the display region DA and signal lines SGL electrically connected to the pixels PX. The display device DD may include a driving circuit GDC and a pad portion PLD which are disposed in the non-display region NDA.

The pixels PX may be arranged in the first direction DR1 and the second direction DR2. The pixels PX may include a plurality of pixel rows extending in the first direction DR1 and arranged in the second direction DR2 and a plurality of pixel columns extending in the second direction DR2 and arranged in the first direction DR1.

The signal lines SGL may include gate lines GL, data lines DL, a power line PL, and a control signal line CSL. Each of the gate lines GL may be connected to a corresponding pixel among the pixels PX, and each of the data lines DL may be connected to a corresponding pixel among the pixels PX. The power line PL may be electrically connected to the pixels PX. The control signal line CSL may be connected to the driving circuit GDC and provide control signals to the driving circuit GDC.

The driving circuit GDC may include a gate driving circuit. The gate driving circuit may generate gate signals and sequentially output the generated gate signals to the gate lines GL. The gate driving circuit may further output a control signal to the pixel driving circuit.

The pad portion PLD may be a portion to which a flexible circuit board is connected. The pad portion PLD may include pixel pads D-PD, and the pixel pads D-PD may be pads for connecting the flexible circuit board to the display panel DP. Each of the pixel pads D-PD may be connected to a corresponding signal line among the signal lines SGL. The pixel pads D-PD may be connected to corresponding pixels PX through the signal lines SGL. In some aspects, any one of the pixel pads D-PD may be connected to the driving circuit GDC.

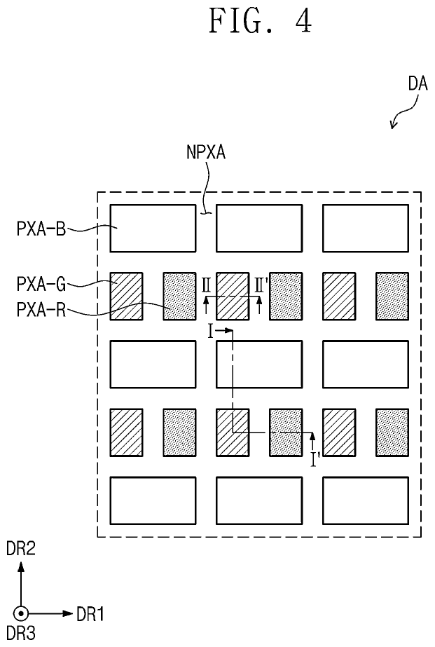

FIG. 4 is an enlarged plan view of a portion of the display device according to an embodiment supported by aspects of the present disclosure. FIG. 4 illustrates a portion of the display region DA (see FIG. 1B) viewed from the display surface IS (see FIG. 1B) of the display device DD (see FIG. 1B). FIG. 4 illustrates an arrangement of light-emitting regions PXA-B, PXA-G, and PXA-R in the display device DD (see FIG. 1B) according to an embodiment supported by aspects of the present disclosure.

The display panel according to an embodiment supported by aspects of the present disclosure may include a plurality of light-emitting regions PXA-B, PXA-G, and PXA-R spaced apart from each other on a plane and a peripheral region NPXA disposed between the light-emitting regions PXA-B, PXA-G, and PXA-R.

The display device according to an embodiment supported by aspects of the present disclosure may include three types of light-emitting regions PXA-B, PXA-G, and PXA-R which are distinguished from each other. In an embodiment supported by aspects of the present disclosure, the three types of light-emitting regions PXA-B, PXA-G, and PXA-R illustrated in FIG. 4 may be repeatedly arranged throughout the display region DA. The light-emitting regions PXA-B, PXA-G, and PXA-R may also be referred to as pixel regions.

The display region DA may emit light of different wavelength ranges and include a first light-emitting region PXA-B, a second light-emitting region PXA-G, and a third light-emitting region PXA-R spaced apart from each other on a plane. In some aspects, the display region DA includes a peripheral region NPXA. The peripheral region NPXA may be referred to as a non-light-emitting region.

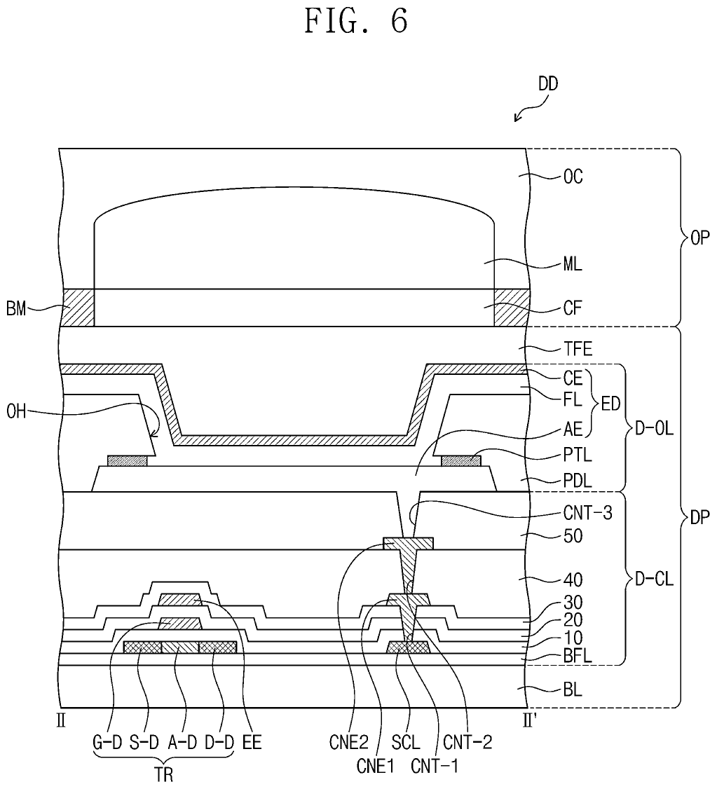

The peripheral region NPXA is disposed surrounding the first to third light-emitting regions PXA-B, PXA-G, and PXA-R. The peripheral region NPXA sets the boundaries of the first to third light-emitting regions PXA-B, PXA-G, and PXA-R. The peripheral region NPXA may surround the first to third light-emitting regions PXA-B, PXA-G, and PXA-R. In the peripheral region NPXA, a structure, such as a pixel defining film PDL (see FIG. 6), configured to prevent color mixing among the first to third pixel regions PXA-B, PXA-G, and PXA-R may be disposed such that the structure corresponds to the peripheral region NPXA.

The first to third light-emitting regions PXA-B, PXA-G, and PXA-R may respectively correspond to regions from which light provided from light-emitting elements ED1, ED2, and ED3 (see FIG. 7) is emitted. The first to third light-emitting regions PXA-B, PXA-G, and PXA-R may be classified according to the color of light emitted toward the outside of the display device DD (see FIG. 1B).

The first to third light-emitting regions PXA-B, PXA-G, and PXA-R may provide first light to third light having different colors. For example, the first light may be blue light, the second light may be green light, and the third light may be red light. However, the examples of the first to third light are not necessarily limited thereto.

Each of the first to third light-emitting regions PXA-B, PXA-G, and PXA-R may correspond to a region in which the upper surface of a first electrode AE1, AE2, or AE3 (see FIG. 7) of a light-emitting element is exposed through a light-emitting opening OH (see FIG. 7), which will be described later. In some aspects, in an embodiment supported by aspects of the present disclosure, each of the first to third light-emitting regions PXA-B, PXA-G, and PXA-R may be defined as a region between pixel defining films PDL (see FIG. 7) that define the light-emitting opening OH (see FIG. 7). For example, in an embodiment supported by aspects of the present disclosure, the light-emitting regions PXA-B, PXA-G, and PXA-R may be defined as regions between the pixel defining films PDL (see FIG. 7) that protrude most toward the light-emitting opening OH (see FIG. 7).

Each of the first to third light-emitting regions PXA-B, PXA-G, and PXA-R may be provided in plurality, and the first to third light-emitting regions PXA-B, PXA-G, and PXA-R may be repeatedly arranged in a predetermined arrangement form in the display region DA. For example, the first light-emitting regions PXA-B may be arranged along the first direction DR1 to form a ‘first group’. The second and third light-emitting regions PXA-G and PXA-R may be alternately arranged along the first direction DR1 to form a ‘second group’. Each of the ‘first group’ and the ‘second group’ may be provided in plurality, and the ‘first groups’ and the ‘second groups’ may be alternately arranged along the second direction DR2.

FIG. 4 illustrates an example arrangement of the first to third light-emitting regions PXA-B, PXA-G, and PXA-R, but embodiments supported by the present disclosure are not limited thereto, and the first to third light-emitting regions PXA-B, PXA-G, and PXA-R may be arranged in various forms. In an embodiment supported by aspects of the present disclosure, the first to third light-emitting regions PXA-B, PXA-G, and PXA-R may have a PENTILE™ arrangement form. Alternatively, the first to third light-emitting regions PXA-B, PXA-G, and PXA-R may have a stripe arrangement form or a Diamond Pixel™ arrangement form.

The first to third light-emitting regions PXA-B, PXA-G, and PXA-R may have various shapes on a plane. For example, each of the first to third light-emitting regions PXA-B, PXA-G, and PXA-R may have a polygonal, circular, or oval shape. In the example illustrated in FIG. 4, the first to third light-emitting regions PXA-B, PXA-G, and PXA-R are illustrated as having a quadrangular shape on a plane.

The first to third light-emitting regions PXA-B, PXA-G, and PXA-R may have the same shape as each other on a plane, or at least some of them may have shapes different from the others. In the example illustrated in FIG. 4, the first to third light-emitting regions PXA-B, PXA-G, and PXA-R have the same shape as each other on a plane.

At least some of the first to third light-emitting regions PXA-B, PXA-G, and PXA-R may have different areas on a plane. In an embodiment supported by aspects of the present disclosure, the area of the first light-emitting region PXA-B configured to emit blue light may be larger than each of the area of the second light-emitting region PXA-G configured to emit green light and the area of the third light-emitting region PXA-R configured to emit red light. However, the size relationship between the areas of the first to third light-emitting regions PXA-B, PXA-G, and PXA-R according to the color of emitted light is not limited thereto and may vary based on the design of the display device according to an embodiment supported by aspects of the present disclosure. In some aspects, without being limited thereto, the first to third light-emitting regions PXA-B, PXA-G, and PXA-R may have the same area as each other on a plane.

In some embodiments, the shape, area, and arrangement of the first to third light-emitting regions PXA-B, PXA-G, and PXA-R in the display device according to an embodiment supported by aspects of the present disclosure may be designed in various ways according to the color of emitted light or the size and configuration of the display device included in the electronic device and are not limited to the example embodiment illustrated in FIG. 4. For example, in an embodiment supported by aspects of the present disclosure, the display device may further include a light-emitting region configured to emit white light in addition to the first to third light-emitting regions PXA-B, PXA-G, and PXA-R.

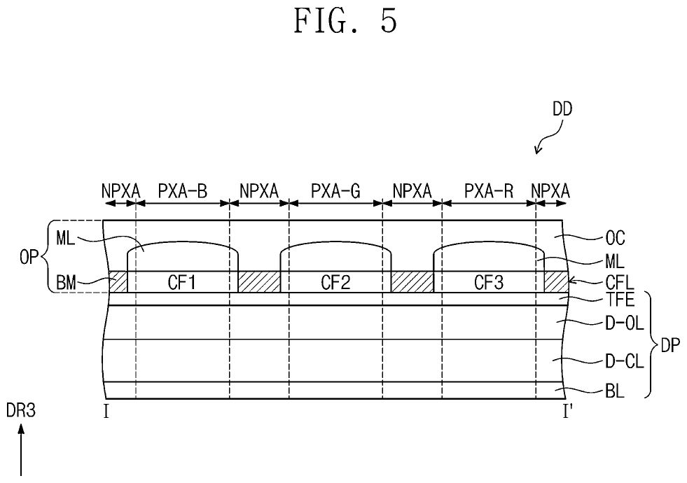

FIG. 5 is a cross-sectional view of the display device according to an embodiment supported by aspects of the present disclosure. In an example, FIG. 5 is a cross-sectional view taken along line I-I′ of FIG. 4.

The display device DD according to an embodiment supported by aspects of the present disclosure may include a display panel DP and a light control panel OP disposed on the display panel DP.

The display panel DP may include a base substrate BL, a circuit element layer D-CL disposed on the base substrate BL, a display element layer D-OL, and an encapsulation layer TFE. The display element layer D-OL may be disposed such that the display element layer D-OL corresponds to the display region DA (see FIGS. 1B and 2B). However, embodiments supported by the present disclosure are not limited thereto, and at least a portion of the display element layer D-OL may be disposed in the non-display region NDA (see FIGS. 1B and 2B).

The base substrate BL may be a support substrate above which the circuit element layer D-CL and the display element layer D-OL are provided. The base substrate BL may include a plastic substrate, a glass substrate, a metal substrate, or an organic/inorganic composite material substrate. In an embodiment supported by aspects of the present disclosure, the base substrate BL may be a silicon substrate, a germanium substrate, or a silicon-on-insulator (SOI) substrate. For example, the base substrate BL may be a single crystal silicon substrate, but embodiments supported by the present disclosure are not limited thereto.

In this specification, the display region DA (see FIGS. 1B and 2B) and the non-display region NDA (see FIGS. 1B and 2B) may be viewed as being defined on the base substrate BL, and in this case, the components disposed on the base substrate BL may be viewed as being disposed to overlap the display region DA (see FIGS. 1B and 2B) or the non-display region NDA (see FIGS. 1B and 2B).

The circuit element layer D-CL includes at least one insulating layer and a circuit element. The circuit element includes a signal line, a pixel driving circuit, and the like. The circuit element layer D-CL may be formed through a process of forming an insulating layer, a semiconductor layer, and a conductive layer by coating, deposition, and other operations, followed by a process of patterning the insulating layer, the semiconductor layer, and the conductive layer through a photolithography process.

The display element layer D-OL includes a light-emitting element ED (see FIG. 6). The light-emitting element ED (see FIG. 6) may include a light-emitting layer and the like which emit light.

The encapsulation layer TFE may include a plurality of thin films. Some of the thin films may be disposed to improve optical efficiency, and others of the thin films may be disposed to protect the light-emitting element.

The encapsulation layer TFE may be a thin film encapsulation layer. The encapsulation layer TFE may be a single layer or a plurality of layers stacked on each other. The encapsulation layer TFE includes at least one insulating layer. The encapsulation layer TFE according to an embodiment supported by aspects of the present disclosure may include at least one inorganic film (hereinafter referred to as an inorganic encapsulation film). In some aspects, the encapsulation layer TFE according to an embodiment supported by aspects of the present disclosure may include at least one organic film (hereinafter referred to as an organic encapsulation film) and at least one inorganic encapsulation film.

The inorganic encapsulation film protects a light-emitting element ED (see FIG. 6) from moisture/oxygen, and the organic encapsulation film protects the light-emitting element ED (see FIG. 6) from foreign substances such as, for example, dust particles. The inorganic encapsulation film may include silicon nitride, silicon oxynitride, silicon oxide, titanium oxide, or aluminum oxide, but embodiments supported by the present disclosure are not particularly limited thereto. The organic encapsulation film may include an acrylic-based compound, an epoxy-based compound, and the like. The organic encapsulation film may include a photopolymerizable organic material, but is not particularly limited thereto.

The light control panel OP may be disposed on the encapsulation layer TFE. The light control panel OP may include a color filter layer CFL, a lens pattern ML, and a cover layer OC.

The color filter layer CFL may include a split pattern BM and at least one color filter CF1, CF2, and CF3. The color filters CF1, CF2, and CF3 transmit light of a specific wavelength range and block light outside the wavelength range. In an embodiment supported by aspects of the present disclosure, the first color filter CF1 may be a blue filter, the second color filter CF2 may be a green filter, and the third color filter CF3 may be a red filter.

Each of the color filters CF1, CF2, and CF3 contains a polymer photosensitive resin and a colorant. The colorant may include a pigment or dye. The first color filter CF1 may include a blue pigment or blue dye, the second color filter CF2 may include a green pigment or green dye, and the third color filter CF3 may include a red pigment or red dye. In an embodiment supported by aspects of the present disclosure, the first color filter CF1 may not contain a pigment or dye.

The first to third color filters CF1, CF2, and CF3 may be respectively disposed to correspond to the first light-emitting region PXA-B, the second light-emitting region PXA-G, and the third light-emitting region PXA-R.

The color filters CF1, CF2, and CF3 may be disposed to correspond to an opening defined in the split pattern BM. The color filters CF1, CF2, and CF3 may transmit light provided from the light-emitting elements ED1, ED2, and ED3 (see FIG. 7) which respectively overlap and correspond to the color filters CF1, CF2, and CF3. The color reproducibility of light provided from the light-emitting elements ED1, ED2, and ED3 (see FIG. 7) may be improved by the color filters CF1, CF2, and CF3. In some aspects, light in a specific wavelength range among the light provided from the light-emitting elements ED1, ED2, and ED3 (see FIG. 7) may be transmitted by the color filters CF1, CF2, and CF3.

Additional or alternative to the example illustrated in FIG. 5, in an embodiment supported by aspects of the present disclosure, the color filter layer CFL may not include a split pattern, and in the color filter layer CFL, a plurality of color filters CF1, CF2, and CF3 configured to transmit different light may be disposed to overlap and correspond to the peripheral region NPXA. In an example, the plurality of color filters CF1, CF2, and CF3 are disposed to overlap and correspond to the peripheral region NPXA in the third direction DR3 which is the thickness direction, which may determine boundaries between adjacent light-emitting regions PXA-B, PXA-G, and PXA-R.

A material constituting the split pattern BM is not particularly limited to the examples described herein, and the material may be any suitable material that absorbs light. The split pattern BM may have a black color, and in an embodiment supported by aspects of the present disclosure, the split pattern BM may include a black coloring agent. The black coloring agent may include black dye and black pigment. The black coloring agent may include carbon black, a metal such as, for example, chromium, or an oxide thereof.

The lens pattern ML may be disposed to overlap each of the light-emitting regions PXA-B, PXA-G, and PXA-R. The lens pattern ML may be disposed on the color filter layer CFL. The lens pattern ML may be disposed on each of the color filters CF1, CF2, and CF3. The lens pattern ML may have a convex shape protruding in a direction away from the display panel DP. The lens pattern ML may have a lens shape. The lens pattern ML may be referred to as a micro lens. However, the shape of the lens pattern ML is not particularly limited. The lens pattern ML may be formed of a material having a refractive index value different from a refractive index value of the cover layer OC. The lens pattern ML may control the direction of light emitted from the light-emitting element ED (see FIG. 6) or improve light extraction efficiency. However, embodiments supported by the present disclosure are not limited thereto.

The cover layer OC may be disposed on the color filter layer CFL. The cover layer OC may cover the color filters CF1, CF2, and CF3, the split pattern BM, and the lens pattern ML. The cover layer OC may be formed from an organic material containing a polymer resin. For example, the cover layer OC may be formed from an organic resin including an acrylic-based resin or an epoxy-based resin. However, embodiments supported by the present disclosure are not limited thereto.

FIG. 6 is a cross-sectional view of a partial region of the display device according to an embodiment supported by aspects of the present disclosure. In an example, FIG. 6 is a cross-sectional view of a portion corresponding to line II-II′ of FIG. 4.

FIG. 6 illustrates an example of cross section of the second light-emitting region PXA-G (see FIG. 4) and a portion corresponding to the periphery of the second light-emitting region. However, the cross section illustrated in FIG. 6 is not limited to the second light-emitting region and the peripheral region of the second light-emitting region, and the cross section may be of a portion corresponding to any one light-emitting region constituting the display device.

Referring to FIG. 6, the display panel DP may include a base substrate BL, a circuit element layer D-CL, a display element layer D-OL, and an encapsulation layer TFE.

The circuit element layer D-CL may include a buffer layer BFL, a transistor TR, a signal transmission region SCL, first to fifth insulating layers 10, 20, 30, 40, and 50, an upper electrode pattern EE, and a plurality of connection electrodes CNE1 and CNE2.

The buffer layer BFL may be disposed on the base substrate BL. The buffer layer BFL may improve bonding strength between the base substrate BL and a semiconductor pattern. The buffer layer BFL may include a silicon oxide layer and a silicon nitride layer. The silicon oxide layer and the silicon nitride layer may be alternately stacked on each other.

The semiconductor pattern may be disposed on the buffer layer BFL. The semiconductor pattern may include polysilicon. Without being limited thereto, however, the semiconductor pattern may include amorphous silicon or a metal oxide. FIG. 6 illustrates an example of a portion of the semiconductor pattern, and the semiconductor pattern may be further disposed in the plurality of light-emitting regions PXA-B, PXA-G, and PXA-R (see FIG. 4). The semiconductor pattern may be arranged in a specific form (e.g., according to one or more design rules, according to a target pattern) across the plurality of light-emitting regions PXA-B, PXA-G, and PXA-R. The semiconductor pattern may have different electrical properties depending on whether the semiconductor pattern is doped or not. The semiconductor pattern may include a first region having a high doping concentration and a second region having a low doping concentration. The first region may be doped with an N-type dopant or a P-type dopant. A P-type transistor may include the first region doped with a P-type dopant.

The first region has higher conductivity than the second region and substantially serves as an electrode or signal line. The second region may substantially correspond to an active (or channel) of a transistor. In other words, a portion of the semiconductor pattern may be an active region of a transistor, another portion of the semiconductor pattern may be a source or drain of the transistor, and still another portion of the semiconductor may be a conductive region of the transistor.

A source S-D, an active region A-D, and a drain D-D of a transistor TR may be formed from the semiconductor pattern. In some aspects, FIG. 6 illustrates a portion of the signal transmission region SCL formed from the semiconductor pattern. Although not separately illustrated, the signal transmission region SCL may be connected to the drain D-D of the transistor TR on a plane.

The first to fifth insulating layers 10, 20, 30, 40, and 50 may be disposed above the buffer layer BFL. The first to fifth insulating layers 10, 20, 30, 40, and 50 may be inorganic layers or organic layers.

The first insulating layer 10 may be disposed on the buffer layer BFL. The first insulating layer 10 may cover the source S-D, active region A-D, and drain D-D of the transistor TR and the signal transmission region SCL which are disposed on the buffer layer BFL. A gate G-D of the transistor TR may be disposed on the first insulating layer 10. The second insulating layer 20 may be disposed on the first insulating layer 10 and cover the gate G-D. The upper electrode pattern EE may be disposed on the second insulating layer 20. The third insulating layer 30 may be disposed on the second insulating layer 20 and cover the upper electrode pattern EE.

The first connection electrode CNE1 may be disposed on the third insulating layer 30. The first connection electrode CNE1 may be connected to the signal transmission region SCL through a contact hole CNT-1 passing through the first to third insulating layers 10, 20, and 30. The fourth insulating layer 40 may be disposed on the third insulating layer 30 and cover the first connection electrode CNE1. The fourth insulating layer 40 may be an organic layer.

The second connection electrode CNE2 may be disposed on the fourth insulating layer 40. The second connection electrode CNE2 may be connected to the first connection electrode CNE1 through a contact hole CNT-2 passing through the fourth insulating layer 40. The fifth insulating layer 50 may be disposed on the fourth insulating layer 40 and cover the second connection electrode CNE2. The fifth insulating layer 50 may be an organic layer.

The display element layer D-OL may be disposed on the circuit element layer D-CL. The display element layer D-OL may include a light-emitting element ED, a pixel defining film PDL, and a protective layer PTL. The protective layer PTL may be directly disposed between the first electrode AE and the pixel defining film PDL. An edge of the protective layer PTL may be positioned such that the edge of the protective layer PTL is more recessed toward the inside of the pixel defining film PDL than an edge of an adjacent pixel defining film PDL.

The light-emitting element ED may include a first electrode AE, a second electrode CE facing the first electrode AE, and a functional layer FL disposed between the first electrode AE and the second electrode CE.

The first electrode AE may be disposed on the circuit element layer D-CL. In an embodiment supported by aspects of the present disclosure, the first electrode AE may be disposed on the fifth insulating layer 50 of the circuit element layer D-CL. The first electrode AE may be connected to the second connection electrode CNE2 through a connection contact hole CNT-3 defined through the fifth insulating layer 50. Accordingly, the first electrode AE may be electrically connected to the signal transmission region SCL through the first and second connection electrodes CNE1 and CNE2 and may be electrically connected to a corresponding circuit element. In an embodiment supported by aspects of the present disclosure, the first electrode AE may have a multi-layered structure in which a plurality of layers are stacked. In some aspects, in an embodiment supported by aspects of the present disclosure, the first electrode AE may be a reflective electrode.

The first electrode AE may be an anode or a cathode. In some aspects, the first electrode AE may be a pixel electrode. The second electrode CE may be a cathode or an anode. The second electrode CE may be a common electrode. In an example in which the first electrode AE is an anode, the second electrode CE may be a cathode. In an example in which the first electrode AE is a cathode, the second electrode CE may be an anode.

The functional layer FL may include at least one light-emitting structure. The functional layer FL may include at least one organic layer commonly provided to the plurality of light-emitting regions PXA-B, PXA-G, and PXA-R (see FIG. 4). In some aspects, the functional layer FL may include a common layer commonly provided to the plurality of light-emitting regions PXA-B, PXA-G, and PXA-R (see FIG. 4) and a light-emitting layer patterned to correspond to each of the light-emitting regions PXA-B, PXA-G, and PXA-R (see FIG. 4). In an alternative example, the functional layer FL may be disconnected in the peripheral region NPXA (see FIG. 4) and be patterned to correspond to each of the light-emitting regions PXA-B, PXA-G, and PXA-R (see FIG. 4). The configuration of the functional layer FL of the light-emitting element ED will be described in more detail later.

In some embodiments, the light-emitting element ED according to an embodiment supported by aspects of the present disclosure may further include a capping layer (not illustrated) disposed on the second electrode CE. The capping layer (not illustrated) may include a plurality of layers or a single layer.

The display element layer D-OL includes a pixel defining film PDL disposed on the circuit element layer D-CL. A light-emitting opening OH is defined in the pixel defining film PDL. The light-emitting opening OH of the pixel defining film PDL exposes at least a portion of the first electrode AE. In an embodiment supported by aspects of the present disclosure, the pixel defining film PDL may cover an edge of the first electrode AE.

The display device DD according to an embodiment supported by aspects of the present disclosure overlaps the pixel defining film PDL and includes a protective layer PTL disposed on the first electrode AE. The first electrode AE may be protected by the protective layer PTL when the pixel defining film PDL is formed during a manufacturing operation of the display device, and the protective layer PTL may also protect the first electrode AE during an operation of patterning and forming the first electrode AE. With respect to the display device DD according to an embodiment supported by aspects of the present disclosure, the patterning of the first electrode AE may be easily performed by introducing the protective layer PTL in a method of manufacturing a display device according to an embodiment supported by aspects of the present disclosure, which will be described later. And “easily perform” refers to reduced manufacturing complexity, reduced number of steps associated with the manufacturing, and protecting components under the protective layer without other protection component.

The protective layer PTL may be directly disposed between the pixel defining film PDL and the first electrode AE, and one side of the protective layer PTL may be exposed through the light-emitting opening OH and may be adjacent to the functional layer FL. In some aspects, an edge of the protective layer PTL exposed by the light-emitting opening OH does not match an edge of the pixel defining film PDL. For example, the edge of the protective layer PTL may be positioned such that the edge of the protective layer PTL is recessed toward the center of the pixel defining film PDL. The protective layer PTL of the display device DD according an embodiment supported by aspects of the present disclosure will be described in more detail later.

The pixel defining film PDL may have a single-layered or multi-layered structure. The pixel defining film PDL may be formed of an inorganic material. For example, the pixel defining film PDL may be formed of an inorganic material such as, for example, silicon nitride (SiNx), silicon oxide (SiOx), or silicon oxynitride (SiOxNy).

However, embodiments supported by the present disclosure are not limited thereto, and the pixel defining film PDL may be formed of a polymer resin. For example, the pixel defining film PDL may be formed by including a polyacrylate-based resin or a polyimide-based resin. In some aspects, the pixel defining film PDL may be formed by further including an inorganic material in addition to the polymer resin. In some embodiments, the pixel defining film PDL may be formed by including a light-absorbing material, or the pixel defining film PDL may be formed by including a black pigment or black dye. The pixel defining film PDL formed by including a black pigment or black dye may implement a black pixel defining film. In an example in which the pixel defining film PDL is formed, carbon black or the like may be used as a black pigment or black dye, but embodiments supported by the present disclosure are not limited thereto.

The encapsulation layer TFE may be disposed on the second electrode CE of the light-emitting element ED. Alternatively, when the light-emitting element ED includes a capping layer (not illustrated), the encapsulation layer TFE may be disposed on the capping layer (not illustrated). The encapsulation layer TFE may cover the light-emitting element ED.

FIG. 7 is a cross-sectional view of a portion of a display panel according to an embodiment supported by aspects of the present disclosure. FIG. 7 may be a cross-sectional view of a portion corresponding to line I-I′ of FIG. 4. The display panel DP may include a base substrate BL, a circuit element layer D-CL, a display element layer D-OL, and an encapsulation layer TFE, which are stacked in the third direction DR3. Regarding the base substrate BL, the circuit element layer D-CL, the display element layer D-OL, and the encapsulation layer TFE, the contents overlapping those described with reference to FIG. 6 will not be described again, and differences will be mainly described.

Referring to FIG. 7, the display panel DP includes first to third light-emitting regions PXA-B, PXA-G, and PXA-R and a peripheral region NPXA disposed between the first to third light-emitting regions PXA-B, PXA-G, and PXA-R.

The light-emitting regions PXA-B, PXA-G, and PXA-R may be defined by being divided by the pixel defining film PDL. In an embodiment supported by aspects of the present disclosure, the first to third light-emitting regions PXA-B, PXA-G, and PXA-R of the display panel DP are respectively defined to correspond to partial regions of the first electrodes AE exposed by the light-emitting openings OH. In an embodiment supported by aspects of the present disclosure, on a cross section parallel to the third direction DR3, each of the first to third light-emitting regions PXA-B, PXA-G, and PXA-R may be defined in association with satisfying a minimum separation distance between the pixel defining films PDL defining the light-emitting opening OH.

The display element layer D-OL may include a pixel defining film PDL and a plurality of light-emitting elements divided by the pixel defining film PDL. The display element layer D-OL may include a first light-emitting element ED1, a second light-emitting element ED2, and a third light-emitting element ED3. The first light-emitting element ED1 may emit blue light, the second light-emitting element ED2 may emit green light, and the third light-emitting element ED3 may emit red light.

The first light-emitting element ED1 may include a first pixel electrode AE1, a first functional layer FL1, and a second electrode CE. The second light-emitting element ED2 may include a second pixel electrode AE2, a second functional layer FL2, and a second electrode CE. The third light-emitting element ED3 may include a third pixel electrode AE3, a third functional layer FL3, and a second electrode CE. Each of the first to third pixel electrodes AE1, AE2, and AE3 may be referred to as a first electrode.

In an embodiment supported by aspects of the present disclosure, the first electrodes AE1, AE2, and AE3 of the first to third light-emitting elements ED1, ED2, and ED3 may be patterned and disposed such that the first electrodes AE1, AE2, and AE3 respectively correspond to the first to third light-emitting regions PXA-B, PXA-G, and PXA-R.

In an embodiment supported by aspects of the present disclosure, the first to third functional layers FL1, FL2, and FL3 may be provided as a common layer and may completely overlap the light-emitting regions PXA-B, PXA-G, and PXA-R and the peripheral region NPXA. In some aspects, in an embodiment supported by aspects of the present disclosure, the second electrode CE may be provided as a common layer and may completely overlap the light-emitting regions PXA-B, PXA-G, and PXA-R and the peripheral region NPXA. However, embodiments supported by the present disclosure are not limited thereto. At least one of the first to third functional layers FL1, FL2, and FL3 and the second electrode CE may be disconnected in the peripheral region NPXA and be disposed to respectively correspond to the light-emitting regions PXA-B, PXA-G, and PXA-R. For example, the first functional layer FL1 and the second electrode CE may be disconnected in the peripheral region NPXA and correspond to the light-emitting regions PXA-B.

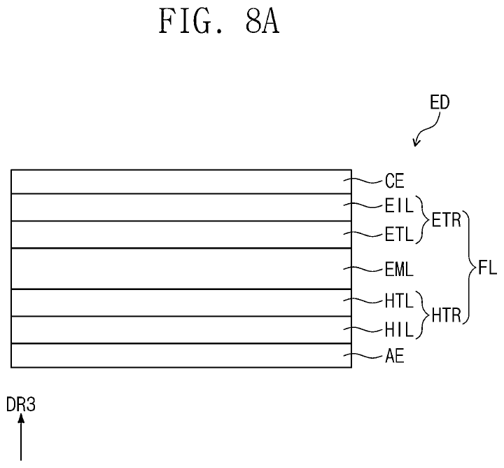

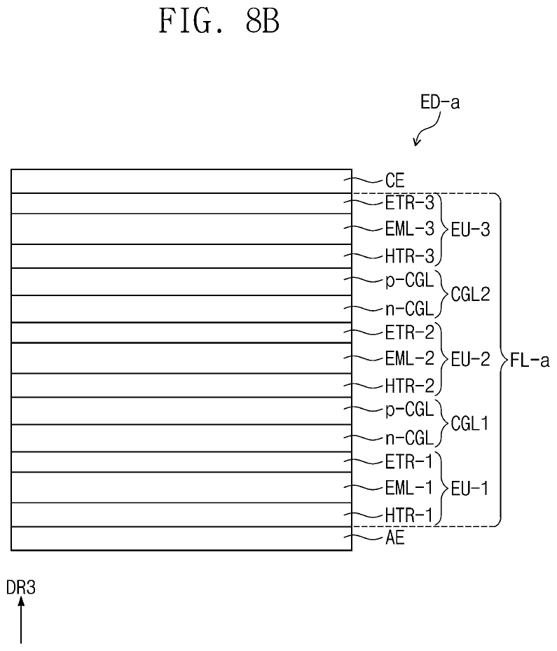

Each of FIGS. 8A and 8B is a cross-sectional view illustrating a light-emitting element according to an embodiment supported by aspects of the present disclosure. Each of the first to third light-emitting elements ED1, ED2, and ED3 in FIG. 7 may have the configuration according to an embodiment of the light-emitting element illustrated in FIG. 8A or 8B.

Referring to FIG. 8A, the light-emitting element ED according to an embodiment supported by aspects of the present disclosure may include a first electrode AE, a functional layer FL, and a second electrode CE, and the functional layer FL may include a hole transport region HTR, a light-emitting layer EML, and an electron transport region ETR. The light-emitting element ED according to an embodiment supported by aspects of the present disclosure may include one light-emitting structure that is a stacked structure of the hole transport region HTR, the light-emitting layer EML, and the electron transport region ETR. That is, each of the first to third functional layers FL1, FL2, and FL3 of the first to third light-emitting elements ED1, ED2, and ED3 illustrated in FIG. 7 may include one light-emitting structure that is a stacked structure of the hole transport region HTR, the light-emitting layer EML, and the electron transport region ETR.

In an embodiment supported by aspects of the present disclosure, the first electrode AE may be formed of a metal material, a metal alloy, or a conductive compound. The first electrode AE may be a reflective electrode. The first electrode AE may contain Ag, Mg, Cu, Al, Pt, Pd, Au, Ni, Nd, Ir, Cr, Li, Ca, LiF/Ca (a stacked structure of LiF and Ca), LiF/Al (a stacked structure of LiF and Al), Mo, Ti, W, or a compound or mixture thereof (e.g., a mixture of Ag and Mg). Alternatively, the first electrode AE may have a multi-layered structure including a reflective or semi-transmissive film formed of the above material and a transparent conductive film formed of an indium tin oxide (ITO), an indium zinc oxide (IZO), a zinc oxide (ZnO), an indium tin zinc oxide (ITZO), or the like. The first electrode AE of the light-emitting element according to an embodiment supported by aspects of the present disclosure, which has a multi-layered structure, will be described in more detail later.

The second electrode CE may be formed of a transparent metal oxide such as, for example, an indium tin oxide (ITO), an indium zinc oxide (IZO), a zinc oxide (ZnO), or an indium tin zinc oxide (ITZO).

In the light-emitting element ED, the light-emitting layer EML may contain a light-emitting material. The light-emitting layer EML may have a single layer formed of a single material, a single layer formed of a plurality of different materials, or a multi-layered structure having a plurality of layers formed of a plurality of different materials. The light-emitting layer may include a fluorescent or phosphorescent material. In the light-emitting element ED according to an embodiment supported by aspects of the present disclosure, the light-emitting layer EML may include an organic light-emitting material, an organic metal complex, a quantum dot, or the like as a light-emitting material.

In some embodiments, the light-emitting layer EML constituting the first to third functional layers FL1, FL2, and FL3 (see FIG. 7) may emit light of different wavelength ranges. Each of the first to third functional layers FL1, FL2, and FL3 (see FIG. 7) may include a light-emitting layer EML containing a light-emitting material different from each other.

In FIG. 8A, the light-emitting element ED is illustrated as including one light-emitting layer EML, but the light-emitting element ED may further include an auxiliary light-emitting layer configured to increase light-emitting efficiency in addition to a main light-emitting layer containing a light-emitting material that emits light of a predetermined color. In some aspects, in an embodiment supported by aspects of the present disclosure, the light-emitting layer EML may have a stacked structure of a plurality of sub-light-emitting layers having different light-emitting material compositions.

The light-emitting element ED may include a hole transport region HTR disposed between the first electrode AE and the light-emitting layer EML. The hole transport region HTR may include at least one of a hole injection layer HIL, a hole transport layer HTL, an auxiliary light-emitting layer, or an electron blocking layer. For example, the hole transport region HTR may include the hole injection layer HIL and the hole transport layer HTL sequentially stacked on the first electrode AE.

In some embodiments, the hole transport region HTR constituting the first to third functional layers FL1, FL2, and FL3 (see FIG. 7) may be formed simultaneously in a same process operation. The hole transport region HTR constituting the first to third functional layers FL1, FL2, and FL3 (see FIG. 7) may be formed of a same material. However, embodiments supported by the present disclosure are not limited thereto.

The light-emitting element ED may include an electron transport region ETR disposed between the light-emitting layer EML and the second electrode CE. The electron transport region ETR may include at least one of a hole blocking layer, an electron transport layer ETL, or an electron injection layer EIL. For example, the electron transport region ETR may include the electron transport layer ETL and the electron injection layer EIL disposed on the light-emitting layer EML, but embodiments supported by the present disclosure are not limited thereto. The electron transport region ETR may have a single-layered structure formed of a single material, a single-layered structure formed of a plurality of different materials, or a multi-layered structure having a plurality of layers formed of a plurality of different materials.

In some embodiments, the electron transport region ETR constituting the first to third functional layers FL1, FL2, and FL3 (see FIG. 7) may be formed simultaneously in a same process operation. The electron transport region ETR constituting the first to third functional layers FL1, FL2, and FL3 (see FIG. 7) may be formed of a same material. However, embodiments supported by the present disclosure are not limited thereto.

Referring to FIG. 8B, a light-emitting element ED-a according to an embodiment supported by aspects of the present disclosure may include a first electrode AE, a functional layer FL-a, and a second electrode CE, and the functional layer FL-a may include a plurality of light-emitting structures EU-1, EU-2, and EU-3. The plurality of light-emitting structures EU-1, EU-2, and EU-3 may respectively include light-emitting layers EML-1, EML-2, and EML-3. Accordingly, the functional layer FL-a may include a plurality of light-emitting layers EML-1, EML-2, and EML-3. That is, the light-emitting element ED-a according to an embodiment supported by aspects of the present disclosure may be a light-emitting element having a tandem structure including the plurality of light-emitting layers EML-1, EML-2, and EML-3 separated from each other. In some embodiments, FIG. 8B illustrates a structure in which three light-emitting structures EU-1, EU-2, and EU-3 are stacked, but embodiments supported by the present disclosure are not limited thereto, and the light-emitting element ED-a may include two light-emitting structures stacked on each other or four or more light-emitting structures stacked on each other. In an embodiment supported by aspects of the present disclosure, the number of the light-emitting structures included in the light-emitting element ED-a may be selected in consideration of the target wavelength range of light for the light-emitting element ED-a.

The light-emitting element ED-a according to an embodiment supported by aspects of the present disclosure may further include charge generation layers CGL1 and CGL2. In an example in which a voltage is applied to the light-emitting element ED-a, the charge generation layers CGL1 and CGL2 may generate charges (electrons and holes) by forming a complex through an oxidation-reduction reaction. The charge generation layers CGL1 and CGL2 may provide the generated charges to each of adjacent light-emitting structures EU-1, EU-2, and EU-3. The charge generation layers CGL1 and CGL2 may increase the efficiency of a current generated in each of the adjacent light-emitting structures EU-1, EU-2, and EU-3 and play a role in adjusting the balance of charges between the adjacent light-emitting structures EU-1, EU-2, and EU-3.

Each of the charge generation layers CGL1 and CGL2 may have a layer structure in which an n-type charge generation layer n-CGL and a p-type charge generation layer p-CGL are bonded to each other.

The n-type charge generation layer n-CGL may provide electrons to adjacent light-emitting structures EU-1, EU-2, and EU-3. The n-type charge generation layer n-CGL may be a layer in which a base material is doped with an n-dopant. The p-type charge generation layer p-CGL may provide holes to adjacent light-emitting structures EU-1, EU-2, and EU-3. The p-type charge generation layer p-CGL may be a layer in which a base material is doped with a p-dopant.

The light-emitting element ED-a may include a first light-emitting structure EU-1, a second light-emitting structure EU-2 disposed on the first light-emitting structure EU-1, and a third light-emitting structure EU-3 disposed on the second light-emitting structure EU-2. The charge generation layer CGL1 may be disposed between the first light-emitting structure EU-1 and the second light-emitting structure EU-2, and the charge generation layer CGL2 may be disposed between the second light-emitting structure EU-2 and the third light-emitting structure EU-3.

The first light-emitting structure EU-1 may include a first hole transport region HTR-1, a first light-emitting layer EML-1, and a first electron transport region ETR-1. The second light-emitting structure EU-2 may include a second hole transport region HTR-2, a second light-emitting layer EML-2, and a second electron transport region ETR-2. The third light-emitting structure EU-3 may include a third hole transport region HTR-3, a third light-emitting layer EML-3, and a third electron transport region ETR-3.

The description of the hole transport region HTR provided with reference to FIG. 8A may be equally applied to the first to third hole transport regions HTR-1, HTR-2, and HTR-3. In some aspects, in the light-emitting element ED-a according to an embodiment supported by aspects of the present disclosure, the first to third hole transport regions HTR-1, HTR-2, and HTR-3 may all have the same structure as each other and be formed of the same material as each other. However, embodiments supported by the present disclosure are not limited thereto, and at least one of the first to third hole transport regions HTR-1, HTR-2, and HTR-3 may have a stacked structure different from a stacked structure of the others, or may be formed by including a hole transport material different from a hole transport material of the others.

The description of the light-emitting layer EML provided with reference to FIG. 8A may be equally applied to the first to third light-emitting layers EML-1, EML-2, and EML-3. In some aspects, in the light-emitting element ED-a according to an embodiment supported by aspects of the present disclosure, the first to third light-emitting layers EML-1, EML-2, and EML-3 may have the same structure as each other and be formed of the same material as each other. However, embodiments supported by the present disclosure are not limited thereto, and at least one of the first to third light-emitting layers EML-1, EML-2, and EML-3 may have a stacked structure different from a stacked structure of the others, or may be formed by including a light-emitting material different from a light-emitting material of the others. In some aspects, each of the first to third light-emitting layers EML-1, EML-2, and EML-3 may include a plurality of sub-light-emitting layers or auxiliary light-emitting layers stacked on each other.

The description of the electron transport region ETR provided with reference to FIG. 8A may be equally applied to the first to third electron transport regions ETR-1, ETR-2, and ETR-3. In some aspects, in the light-emitting element ED-a according to an embodiment supported by aspects of the present disclosure, the first to third electron transport regions ETR-1, ETR-2, and ETR-3 may all have the same structure as each other and be formed of the same material as each other. However, embodiments supported by the present disclosure are not limited thereto, and at least one of the first to third electron transport regions ETR-1, ETR-2, and ETR-3 may have a stacked structure different from a stacked structure of the others, or may be formed by including an electron transport material different from an electron transport material of the others.

In some embodiments, the light-emitting structures EU-1, EU-2, and EU-3 constituting the first to third functional layers FL1, FL2, and FL3 (see FIG. 7) may emit light of different wavelength ranges. The first to third functional layers FL1, FL2, and FL3 (see FIG. 7) may be functional layers FL-a each containing a different light-emitting material.

In some aspects, in an embodiment supported by aspects of the present disclosure, the first to third light-emitting structures EU-1, EU-2, and EU-3 of the light-emitting element ED-a may respectively emit light of different wavelength ranges. Accordingly, the light-emitting element ED-a according to an embodiment supported by aspects of the present disclosure may emit light that is a combination of light provided from each of the light-emitting structures EU-1, EU-2, and EU-3. For example, in the display device DD (see FIG. 7) according to an embodiment supported by aspects of the present disclosure, the first to third light-emitting elements ED1, ED2, and ED3 may emit light in a same wavelength range, and the light may be filtered and emitted by the light control panel OP (see FIG. 5) as light in a wavelength range corresponding to each of the light-emitting regions PXA-B, PXA-G, and PXA-R.

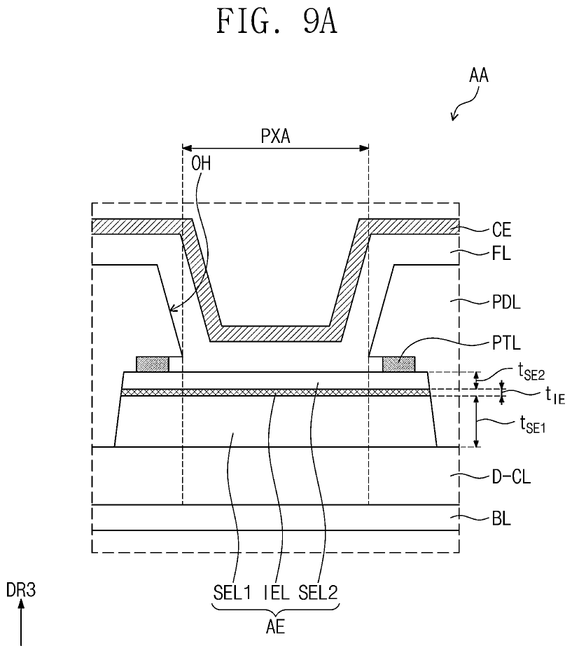

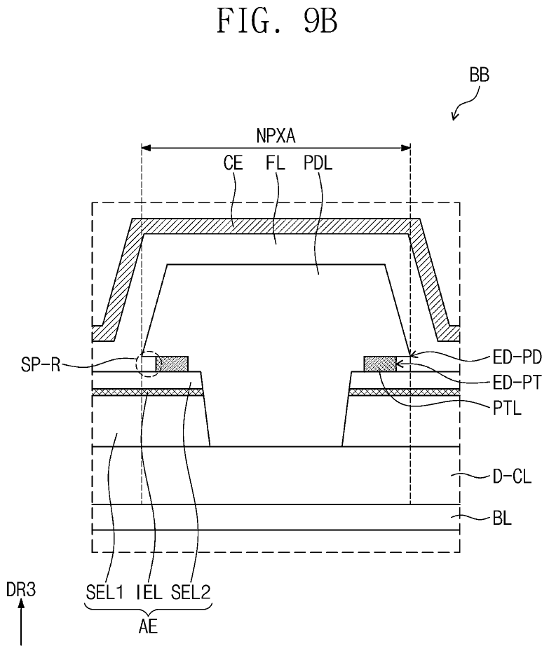

FIGS. 9A and 9B are cross-sectional views each illustrating a portion of the display panel according to an embodiment supported by aspects of the present disclosure. FIG. 9A is a cross-sectional view illustrating a portion corresponding to a region “AA” of FIG. 7, and FIG. 9B is a cross-sectional view illustrating a portion corresponding to a region “BB” of FIG. 7. That is, the illustration of FIG. 9A is centered on the light-emitting region PXA among the display panel according to an embodiment supported by aspects of the present disclosure, and the illumination of FIG. 9B is centered on the peripheral region NPXA among the display panel according to an embodiment supported by aspects of the present disclosure.

The region “AA” is selected as a portion corresponding to the second light-emitting region PXA-G in FIG. 7, but this is an example, and the structure illustrated in FIG. 9A may be equally applied to the remaining light-emitting regions PXA-B and PXA-R.

In an embodiment supported by aspects of the present disclosure, the first electrode AE has a multi-layered structure in which a plurality of layers are stacked. The first electrode AE may be a reflective electrode. The first electrode AE may include a first sub-electrode SEL1, a second sub-electrode SEL2 disposed on the first sub-electrode, and an intermediate layer IEL disposed between the first sub-electrode SEL1 and the second sub-electrode SEL2. The intermediate layer IEL may be directly disposed between the first sub-electrode SEL1 and the second sub-electrode SEL2.

The first sub-electrode SEL1 may be a reflective electrode including a reflective metal material. The first sub-electrode SEL1 may include aluminum (Al) or an aluminum alloy. For example, the aluminum alloy may include titanium (Ti), neodymium (Nd), lanthanum (La), nickel (Ni), tantalum (Ta), or the like in addition to aluminum. A thickness t_{SE1} of the first sub-electrode SEL1 may range from about 600 Å (angstrom) to about 1000 Å. For example, the thickness t_{SE1} of the first sub-electrode SEL1 may range from about 700 Å to about 1000 Å. Specifically, the thickness t_{SE1} of the first sub-electrode SEL1 may be about 900 Å. However, embodiments supported by the present disclosure are not limited thereto.

The second sub-electrode SEL2 may include a transparent conductive oxide. The second sub-electrode SEL2 may include a polycrystalline ITO (p-ITO). In some aspects, including the second sub-electrode SEL2 in the first electrode AE may improve the hole injection function of the light-emitting element.

The thickness t_{SE2} of the second sub-electrode SEL2 may range from about 20 Å to about 100 Å. In some cases, if the thickness t_{SE2} of the second sub-electrode SEL2 is less than about 20 Å, the electrical characteristics of the light-emitting element may be deteriorated, and if the thickness t_{SE2} of the second sub-electrode SEL2 is more than about 100 Å, an etching process does not proceed smoothly during the formation of the first electrode AE. In an example, the thickness t_{SE2} of the second sub-electrode SEL2 may range from about 20 Å to about 50 Å. Specifically, the thickness t_{SE2} of the second sub-electrode SEL2 may be about 30 Å.

The intermediate layer IEL may be disposed between the first sub-electrode SEL1 and the second sub-electrode SEL2. The intermediate layer IEL may be directly disposed between the first sub-electrode SEL1 and the second sub-electrode SEL2 to reduce contact resistance in the first electrode AE. The intermediate layer IEL may include a tungsten oxide (WOx). In some aspects, including the intermediate layer IEL formed of a tungsten oxide between the first sub-electrode SEL1 and the second sub-electrode SEL2 may significantly reduce contact resistance, when compared to a case in which the second sub-electrode SEL2 is directly disposed on the first sub-electrode SEL1. In an example in which the intermediate layer IEL formed of a tungsten oxide is included, the contact resistance may be reduced by about 1/100, compared to a case of having a stacked structure of the first sub-electrode SEL1 and the second sub-electrode SEL2 without the intermediate layer IEL. This is because the intermediate layer IEL formed of a tungsten oxide prevents an aluminum oxide film from being formed on the first sub-electrode SEL1 formed by including aluminum, thereby reducing the deterioration of electrical characteristics due to an aluminum oxide film.

For example, in a structure in which an aluminum (Al) layer and an ITO layer are directly disposed, a contact resistance (Rc) may have a value of about 10⁻² to about 10⁻¹ Ωcm², and in a structure in which an aluminum (Al) layer and a tungsten oxide (WOx) layer having the same thickness as each other are stacked, the contact resistance (Rc) may have a value of about 10⁻⁴ Ωcm². That is, it can be seen that the contact resistance is significantly reduced when the tungsten oxide is disposed directly on aluminum, compared to when the ITO layer is disposed directly on aluminum which is a reflective metal material.

Therefore, the light-emitting element ED1, ED2, and ED3 (see FIG. 7) including the first electrode AE having a stacked structure of the first sub-electrode SEL1 containing a reflective metal material such as, for example, aluminum, the intermediate layer IEL containing a tungsten oxide, and the second sub-electrode SEL2 containing a transparent conductive oxide may exhibit low driving voltage characteristics, compared to a case in which the intermediate layer IEL is not included.

A thickness t_{IE} of the intermediate layer IEL may be about 30 Å or less. For example, the thickness t_{IE} of the intermediate layer IEL may range from about 5 Å to about 30 Å. By providing the intermediate layer IEL having a thickness of about 30 Å or less, the formation of the first electrode AE having a stacked structure of the first sub-electrode SEL1, the intermediate layer IEL, and the second sub-electrode SEL2 may be easily performed. In some aspects, by providing the intermediate layer IEL having a thickness of about 30 Å or less, light absorption in the intermediate layer IEL may be minimized. Accordingly, the reflective characteristics of the first electrode AE, which is a reflective electrode, may be maintained.

Referring to FIGS. 7 and 9A, the light-emitting region PXA, in which the light-emitting opening OH is defined, may overlap the first sub-electrode SEL1, the intermediate layer IEL, and the second sub-electrode SEL2 and may not overlap the protective layer PTL. The functional layer FL may be directly disposed on the second sub-electrode SEL2 in the light-emitting region PXA.

The region “BB” illustrated in FIG. 9B is selected as a portion adjacent to the second light-emitting region PXA-G in FIG. 7, but this is an example, and the structure illustrated in FIG. 9B may be equally applied to the remaining peripheral region NPXA.

Referring to FIGS. 7 and 9B, in the peripheral region NPXA adjacent to the light-emitting region PXA (see FIG. 9A), the first sub-electrode SEL1, the intermediate layer IEL, the second sub-electrode SEL2, and the protective layer PTL may be disposed overlapping each other. That is, in the peripheral region NPXA adjacent to the light-emitting region PXA (see FIG. 9A), the protective layer PTL may be directly disposed between the first electrode AE and the pixel defining film PDL.

The protective layer PTL may be formed of an amorphous transparent conductive oxide film. For example, the protective layer PTL may include at least one of indium gallium zinc oxide (IGZO), IZO, or zinc indium tin oxide (Zn-ITO). In some aspects, a transparent conductive oxide material included in the protective layer PTL may have an amorphous structure. For example, the protective layer PTL may include amorphous IGZO.

The protective layer PTL may function to protect the first electrode AE in a process of manufacturing the display device. That is, the protective layer PTL may prevent damage to the first electrode AE during etching operations in the process of manufacturing the display device. In some aspects, the protective layer PTL is formed of an amorphous transparent conductive oxide film and therefore may be easily removed or patterned by wet etching.

The thickness of the protective layer PTL may range from about 50 Å to about 200 Å. For example, the thickness of the protective layer PTL may be about 100 Å. In some cases, if the thickness of the protective layer PTL is less than about 50 Å, the function to protect the first electrode AE may not be sufficient, and if the thickness of the protective layer PTL is more than about 200 Å, disconnection of the second electrode CE may occur due to a step difference between the protective layer PTL and the pixel defining film PDL.

Referring to FIGS. 7 and 9B, one edge ED-PT of the protective layer PTL exposed toward the light-emitting opening OH may be positioned such that the edge ED-PT is more recessed toward the inside of the pixel defining film PDL than an edge ED-PD of the pixel defining film PDL corresponding to a boundary of the light-emitting regions PXA-B, PXA-G, and PXA-R and the peripheral region NPXA. Accordingly, a recessed region SP-R in which the protective layer PTL is not disposed may be defined between the pixel defining film PDL and the first electrode AE in the peripheral region NPXA. In the recessed region SP-R, a functional layer FL may be disposed between the first electrode AE and the pixel defining film PDL. A structure in which the edge ED-PT of the protective layer PTL is more recessed from the light-emitting regions PXA-B, PXA-G, and PXA-R than the edge ED-PD of the pixel defining film PDL may be introduced by an etching process which forms the protective layer PTL after the first electrode AE and the pixel defining film PDL are formed in a method of manufacturing the display deice according to an embodiment supported by aspects of the present disclosure, which has been described herein. For example, the protective layer PTL may be finally formed by wet etching, and since the protective layer PTL is removed from a portion of the lower portion of the pixel defining film PDL in a wet-etching process, a characteristic in which the edge ED-PT of the protective layer PTL is more recessed than the edge ED-PD of the pixel defining film PDL may be exhibited. Accordingly, the pixel defining film PDL may have a stepped structure in a portion of the peripheral region NPXA adjacent to the light-emitting regions PXA-B, PXA-G, and PXA-R. In an embodiment supported by aspects of the present disclosure, the stepped portion may be filled with the functional layer FL.

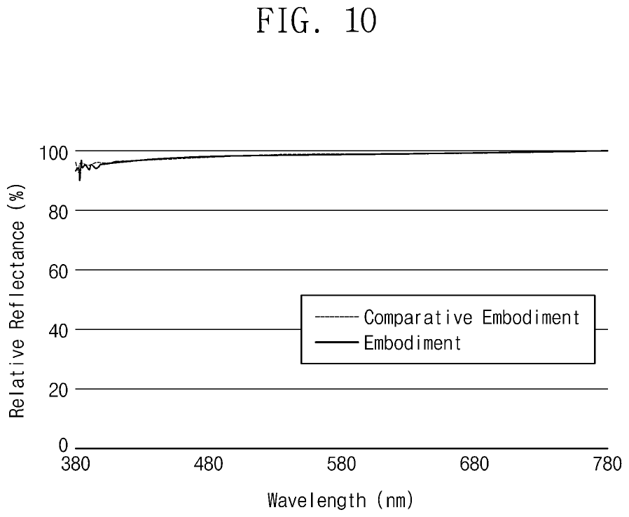

FIG. 10 is a graph illustrating relative reflectance characteristics according to wavelength. In FIG. 10, a comparative embodiment is a stacked structure of aluminum and an indium tin oxide (ITO), and an embodiment according to aspects of the present disclosure is a stacked structure of aluminum and a tungsten oxide film. In an example in which the stacked structure of the comparative embodiment and the stacked structure of the embodiment are of the same thickness, the case of the embodiment in which a tungsten oxide film is used has exhibited a reflection characteristic similar to a reflection characteristic of the comparative embodiment in which an indium tin oxide (ITO) is used. That is, it can be seen that the embodiment in which the tungsten oxide film is used in the entire visible light region has exhibited a reflection characteristic similar to the reflection characteristic of the comparative embodiment in which the indium tin oxide (ITO) is used. Therefore, it can be seen that the first electrode may maintain an excellent reflection characteristic (e.g., relative reflectance satisfying a target percentage) even when a tungsten oxide is used as an intermediate layer.

Referring to FIGS. 7, 9A, 9B, and 10, the display device DD according to an embodiment supported by aspects of the present disclosure includes the first electrode AE including a first sub-electrode SEL1 containing a reflective metal material, a second sub-electrode SEL2 disposed on the first sub-electrode and containing a transparent conductive oxide, and an intermediate layer IEL disposed directly between the first sub-electrode and the second sub-electrode and containing a tungsten oxide, and the display device DD exhibits excellent electrical characteristics without an increase in driving voltage, and further, excellent reflective electrode characteristics. In some aspects, the first electrode AE of the display device DD according to an embodiment supported by aspects of the present disclosure may be well protected by the protective layer PTL in a manufacturing process, and the resulting display device DD may exhibit excellent film characteristics and display quality.

FIG. 11 is a cross-sectional view illustrating a display panel according to an embodiment supported by aspects of the present disclosure. A display panel DP-a according to an embodiment supported by aspects of the present disclosure illustrated in FIG. 11 is different in the arrangement of functional layers FL1-a, FL2-a, and FL3-a from the display panel DP according to the embodiment supported by aspects of the present disclosure illustrated in FIG. 7. The first functional layer FL1-a, the second functional layer FL2-a, and the third functional layer FL3-a respectively included in the first light-emitting element ED1-a, the second light-emitting element ED2-a, and the third light-emitting element ED3-a may be patterned separately from each other. The functional layers FL1-a, FL2-a, and FL3-a may be disposed such that the functional layers FL1-a, FL2-a, and FL3-a respectively correspond to the light-emitting regions PXA-B, PXA-G, and PXA-R and may extend to a portion of the peripheral region NPXA adjacent to the light-emitting regions PXA-B, PXA-G, and PXA-R.

The contents described with reference to FIGS. 8A and 8B may be equally applied to the light-emitting elements ED1-a, ED2-a, and ED3-a included in the display panel DP-a according to an embodiment supported by aspects of the present disclosure. For example, each of the functional layers FL1-a, FL2-a, and FL3-a disconnected from each other in the peripheral region NPXA of the display panel DP-a according to an embodiment supported by aspects of the present disclosure may have the structure of the functional layer FL or FL-a illustrated in FIGS. 8A and 8B. However, embodiments supported by the present disclosure are not limited thereto. For example, among the functional layers FL and FL-a illustrated in FIGS. 8A and 8B, the light-emitting layers EML, EML-1, EML-2, and EML-3 may be patterned such that the light-emitting layers EML, EML-1, EML-2, and EML-3 respectively correspond to the light-emitting regions PXA-B, PXA-G, and PXA-R, and other organic layers such as, for example, the hole transport regions HTR, HTR-1, HTR-2, and HTR-3, the electron transport regions ETR, ETR-1, ETR-2, and ETR-3, and the charge generation layers CGL1 and CGL2 may be commonly provided in the light-emitting regions PXA-B, PXA-G, and PXA-R and the peripheral region NPXA.

The display device DD according to an embodiment supported by aspects of the present disclosure includes the first electrode AE including a first sub-electrode SEL1 containing a reflective metal material, a second sub-electrode SEL2 disposed on the first sub-electrode and containing a transparent conductive oxide, and an intermediate layer IEL disposed directly between the first sub-electrode and the second sub-electrode and containing a tungsten oxide, which may support a reduced contact resistance and an exhibition of excellent electrical characteristics without an increase in driving voltage. In some aspects, the display device DD according to an embodiment supported by aspects of the present disclosure includes an intermediate layer containing a tungsten oxide, and the display device DD may exhibit excellent reflective electrode characteristics while maintaining excellent electrical characteristics.

In some embodiments, in the display device according to an embodiment supported by aspects of the present disclosure, the first electrode composed of three layers including the intermediate layer provided with a thickness of 30 Å or less and the second sub-electrode provided with a thickness of 100 Å or less may be formed by collective etching in a single process operation, and since the first electrode may be formed by dry etching, it may be possible to implement an ultra-high resolution display device through a fine patterning process.

In some aspects, since a protective layer is provided between the first electrode and the pixel defining film and the first electrode is sufficiently protected during an etching process, the film characteristics of the first electrode may be maintained and excellent electrical characteristics may be achieved.

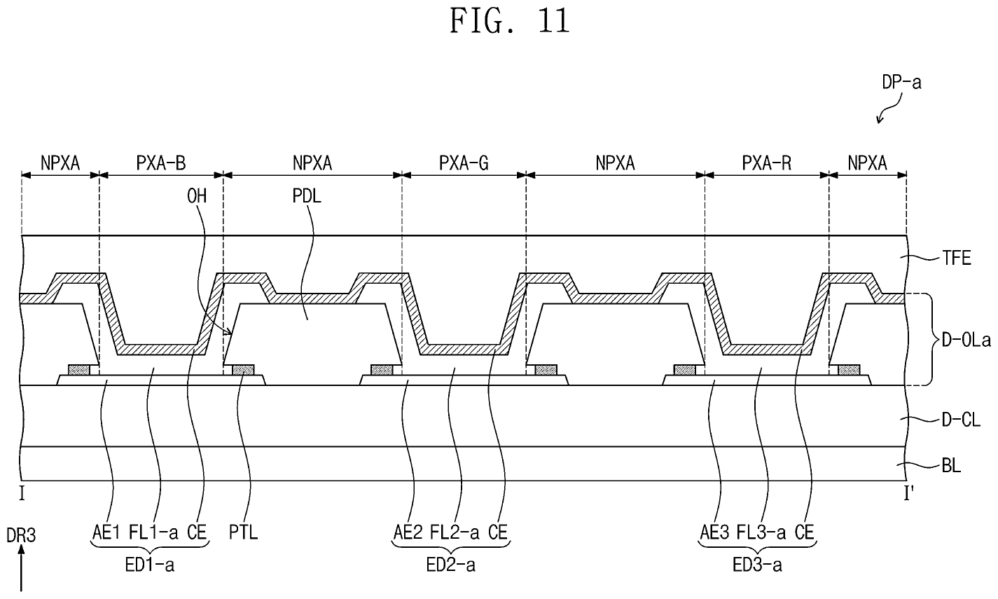

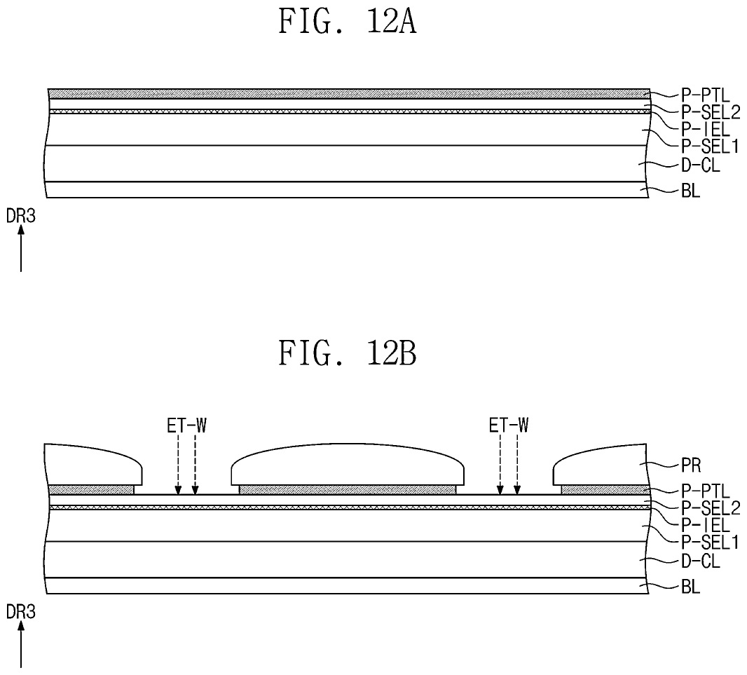

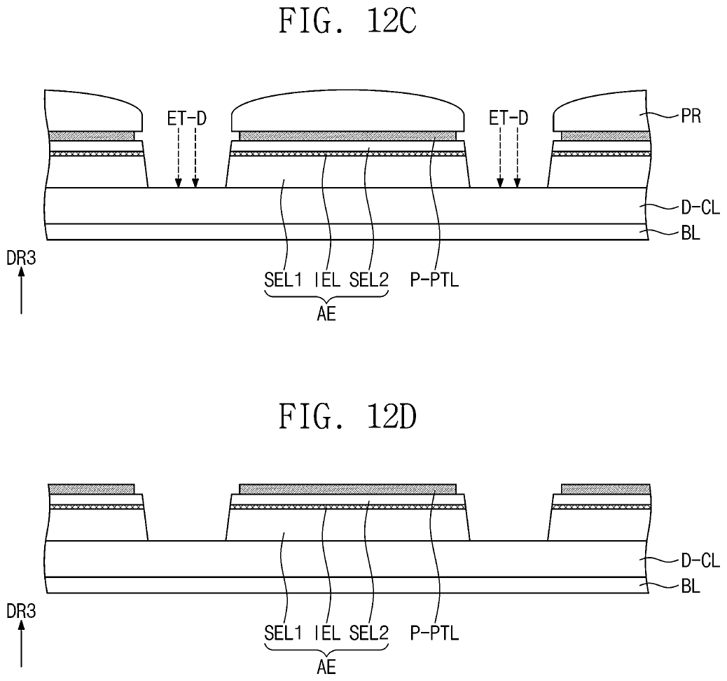

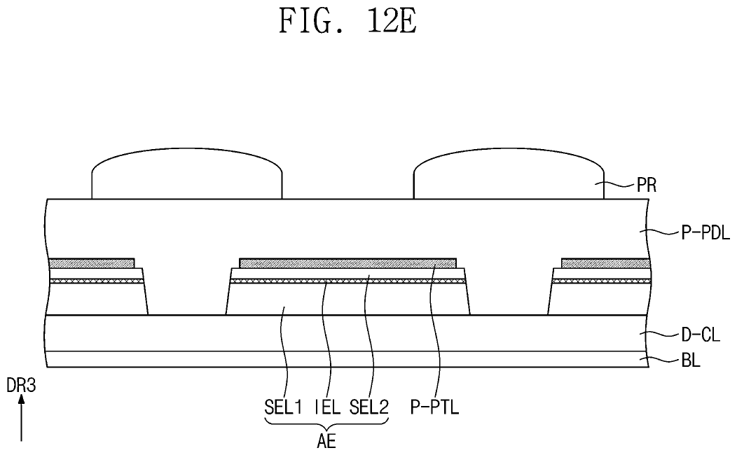

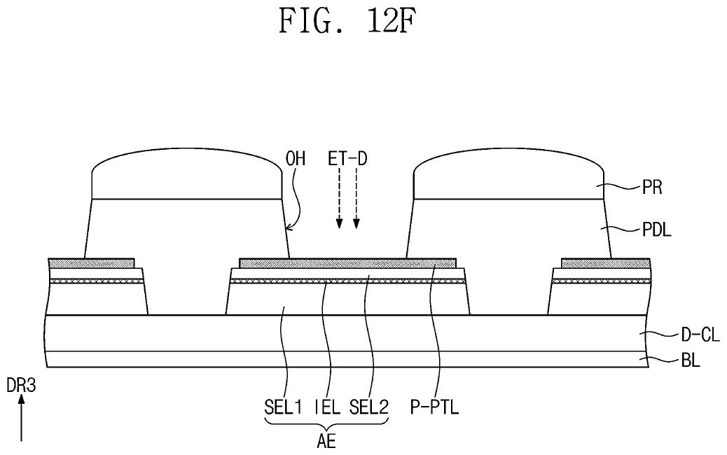

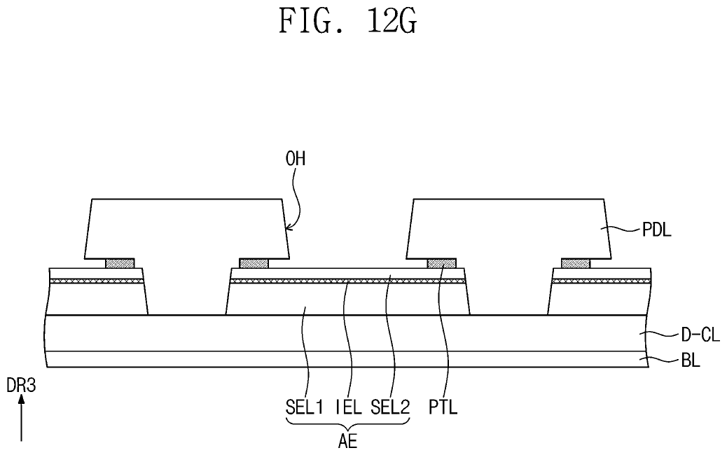

Hereinafter, a method of manufacturing a display device according to an embodiment supported by aspects of the present disclosure will be described with reference to FIGS. 12A to 12G. FIGS. 12A to 12G illustrate operations of a method for manufacturing a display device according to an embodiment supported by aspects of the present disclosure. In describing FIGS. 12A to 12G, the same/similar reference numerals will be used for the same/similar components as those described with reference to FIGS. 1A to 11, and duplicate descriptions will be omitted.

In the descriptions of the method and processes herein, the operations may be performed in a different order than the order shown and/or described, or the operations may be performed in different orders or at different times. Certain operations may also be left out of the method and processes, one or more operations may be repeated, or other operations may be added. Descriptions that an element “may be disposed,” “may be formed,” and the like include methods, processes, and techniques for disposing, forming, positioning, and modifying the element, and the like in accordance with example aspects described herein.

The method of manufacturing the display device according to an embodiment supported by aspects of the present disclosure may include sequentially providing a preliminary first sub-electrode, a preliminary intermediate layer, a preliminary second sub-electrode, and a preliminary protective layer on a circuit element layer. The method may include patterning the preliminary protective layer by removing a portion of the preliminary protective layer. The method may include forming a first electrode by etching portions of the preliminary first sub-electrode, the preliminary intermediate layer, and the preliminary second sub-electrode which overlap a region from which the portion of the preliminary protective layer is removed. The method may include providing a preliminary pixel defining film layer on the formed first electrode. The method may include forming a pixel defining film by patterning the preliminary pixel defining film layer, where a light-emitting opening is defined in the pixel defining film. The method may include forming a protective layer by removing a portion of the preliminary protective layer exposed through the light-emitting opening, where an edge of the protective layer exposed through the light-emitting opening is positioned such that the edge of the protective layer is more recessed toward an inside of the pixel defining film than an edge of the pixel defining film.

FIG. 12A illustrates an example of sequentially providing a preliminary first sub-electrode, a preliminary intermediate layer, a preliminary second sub-electrode, and a preliminary protective layer.

Referring to FIG. 12A, the method may include disposing a circuit element layer D-CL on the base substrate BL, and the method may include sequentially providing a preliminary first sub-electrode P-SEL1, a preliminary intermediate layer P-IEL, a preliminary second sub-electrode P-SEL2, and a preliminary protective layer P-PTL on the circuit element layer D-CL. In the display device according to an embodiment supported by aspects of the present disclosure, the preliminary first sub-electrode P-SEL1, the preliminary intermediate layer P-IEL, and the preliminary second sub-electrode P-SEL2 may be formed such that the preliminary first sub-electrode P-SEL1, the preliminary intermediate layer P-IEL, and the preliminary second sub-electrode P-SEL2 respectively correspond to the first sub-electrode SEL1 (see FIG. 7), the intermediate layer IEL (see FIG. 7), and the second sub-electrode SEL2 (see FIG. 7). In some aspects, the preliminary protective layer P-PTL may be formed to correspond to the protective layer PTL (see FIG. 7). That is, in this specification, the preliminary first sub-electrode P-SEL1, the preliminary intermediate layer P-IEL, the preliminary second sub-electrode P-SEL2, and the preliminary protective layer P-PTL may refer to a state of an element prior to being formed through post-process steps to finally correspond to the first sub-electrode SEL1 (see FIG. 7), the intermediate layer IEL (see FIG. 7), the second sub-electrode SEL2 (see FIG. 7), and the protective layer PTL (see FIG. 7), respectively.

The method may include sequentially providing the preliminary first sub-electrode P-SEL1, the preliminary intermediate layer P-IEL, the preliminary second sub-electrode P-SEL2, and the preliminary protective layer P-PTL such that the preliminary first sub-electrode P-SEL1, the preliminary intermediate layer P-IEL, the preliminary second sub-electrode P-SEL2, and the preliminary protective layer P-PTL overlap the entire circuit element layer D-CL.

The descriptions provided with respect to the first sub-electrode SEL1, the intermediate layer IEL, the second sub-electrode SEL2, and the protective layer PTL, which are described herein with respect to the display device according to an embodiment supported by aspects of the present disclosure, may be equally applied to the configuration of the preliminary first sub-electrode P-SEL1, the preliminary intermediate layer P-IEL, the preliminary second sub-electrode P-SEL2, and the preliminary protective layer P-PTL.

For example, the preliminary first sub-electrode P-SEL1 may include aluminum or an aluminum alloy, and the preliminary second sub-electrode P-SEL2 may include a polycrystalline ITO. In some aspects, the preliminary intermediate layer P-IEL may include a tungsten oxide. The preliminary protective layer P-PTL may include an amorphous transparent conductive oxide film.

In some aspects, the preliminary first sub-electrode P-SEL1 may be provided with a thickness ranging from about 600 Å to about 1000 Å, and the preliminary intermediate layer P-IEL may be provided with a thickness of about 30 Å or less on the preliminary first sub-electrode P-SEL1. The preliminary second sub-electrode P-SEL2 may be provided with a thickness of about 20 Å to about 100 Å on the preliminary intermediate layer P-IEL. The preliminary intermediate layer P-IEL containing a tungsten oxide is provided with a thickness of about 30 Å or less between the preliminary first sub-electrode P-SEL1 and the preliminary second sub-electrode P-SEL2, which may reduce a contact resistance between the two electrodes. The preliminary intermediate layer P-IEL containing a tungsten oxide may be provided with a thickness greater than a minimum thickness for reducing contact resistance between the preliminary first sub-electrode P-SEL1 and the preliminary second sub-electrode P-SEL2, and in some embodiments, the thickness of the preliminary intermediate layer P-IEL may be about 30 Å or less. In some aspects, providing the preliminary intermediate layer P-IEL such that the thickness is about 30 Å or less may provide improved contact resistance between the two sub-electrodes and support easily performing patterning in a single etching process, example aspects of which will be described later. In some aspects, providing the preliminary second sub-electrode P-SEL2 having a thickness of about 20 Å to about 100 Å may support easily performing patterning in a single etching process, example aspects of which will be described later.

FIG. 12B illustrates an example of patterning by removing a portion of the preliminary protective layer. The patterning by removing a portion of the preliminary protective layer may include forming a photosensitive pattern PR on the preliminary protective layer P-PTL and removing a portion of the preliminary protective layer P-PTL which is non-overlapping the photosensitive pattern PR by a wet etching ET-W method. In an example, the wet etching ET-W method includes providing an etching solution on the upper side of the preliminary protective layer P-PTL. That is, a portion of the preliminary protective layer P-PTL on which the photosensitive pattern PR is not provided may be removed by a wet etching ET-W method. In the operation of patterning by removing a portion of the preliminary protective layer, when the display device is manufactured, the method may include providing the photosensitive pattern PR at regions respectively corresponding to the first electrodes AE1, AE2, and AE3 (see FIG. 7) which are disposed spaced apart from each other on the circuit element layer D-CL (see FIG. 7). That is, in the operation of patterning by removing a portion of the preliminary protective layer, the method may include providing the photosensitive pattern PR for patterning in consideration of the arrangement of the first electrodes AE1, AE2, and AE3 (see FIG. 7).

The method may include removing a portion of the preliminary protective layer P-PTL by a wet etching ET-W method, such that the upper surface of the preliminary second sub-electrode P-SEL2 may be exposed in a region where the preliminary second sub-electrode P-SEL2 does not overlap the photosensitive pattern PR.

FIGS. 12C and 12D illustrate an example of forming a first electrode by etching the preliminary first sub-electrode, the preliminary intermediate layer, and the preliminary second sub-electrode. The method may include patterning the preliminary first sub-electrode P-SEL1 (see FIG. 12B), the preliminary intermediate layer P-IEL (see FIG. 12B), and the preliminary second sub-electrode P-SEL2 (see FIG. 12B) overlapping a region from which the preliminary protective layer is removed to form a first electrode AE in which the first sub-electrode SEL1, the intermediate layer IEL, and the second sub-electrode SEL2 are stacked.

The forming of the first electrode may include dry etching ET-D the preliminary first sub-electrode P-SEL1 (see FIG. 12B), the preliminary intermediate layer P-IEL (see FIG. 12B), and the preliminary second sub-electrode P-SEL2 (see FIG. 12B) through a same process step. That is, the material composition and thickness ratio of the preliminary first sub-electrode P-SEL1 (see FIG. 12B), the preliminary intermediate layer P-IEL (see FIG. 12B), and the preliminary second sub-electrode P-SEL2 (see FIG. 12B) may support collective dry etching of the preliminary first sub-electrode P-SEL1 (see FIG. 12B), the preliminary intermediate layer P-IEL (see FIG. 12B), and the preliminary second sub-electrode P-SEL2 (see FIG. 12B), which are described herein, in one process operation. That is, the method may include forming the first electrode AE, in which the first sub-electrode SEL1, the intermediate layer IEL, and the second sub-electrode SEL2 are stacked, in a fine pattern by using a collective dry etching method. In some aspects, the collective dry etching of the preliminary first sub-electrode P-SEL1 (see FIG. 12B) containing aluminum or the like as described herein, the preliminary intermediate layer P-IEL (see FIG. 12B) containing a tungsten oxide, and the preliminary second sub-electrode P-SEL2 (see FIG. 12B) containing a polycrystalline ITO in one process operation may support precise patterning and forming of the first electrode AE having a multi-layered structure.

In the method of manufacturing the display device according to an embodiment supported by aspects of the present disclosure, due to the stacked structure of the first sub-electrode SEL1 containing aluminum or the like as described herein, the intermediate layer IEL containing a tungsten oxide, and the second sub-electrode SEL2 containing a polycrystalline ITO, contact resistance in the first electrode may be reduced, and the display device according to an embodiment supported by aspects of the present disclosure may exhibit improved electrical characteristics. In some aspects, since the method of manufacturing the display device according to an embodiment supported by aspects of the present disclosure includes the forming of the first electrode by using a collective dry etching method, the first electrode AE may have a characteristic in which the first electrode AE can be accurately patterned in a fine pattern, which supports high resolution of a display device DD. In some aspects, since the first electrode AE having a multi-layered structure may be formed through collective patterning in one process operation, process productivity may be improved in the method of manufacturing the display device according to an embodiment supported by aspects of the present disclosure.

After the first electrode AE is formed through collective dry etching, the method may include removing a remaining photosensitive pattern PR overlapping the first electrode AE. FIG. 12D illustrates an example of state in which the photosensitive pattern PR patterned on the preliminary protective layer P-PTL has been removed and the first electrode AE and the preliminary protective layer P-PTL disposed on the first electrode AE remain.

FIG. 12E illustrates an example of providing a preliminary pixel defining film layer on the formed first electrode, and FIG. 12F illustrates an example of patterning the preliminary pixel defining film layer to form a pixel defining film having a light-emitting opening defined therein.

In an embodiment supported by aspects of the present disclosure, the forming of the pixel defining film may include forming a photosensitive pattern on the preliminary pixel defining film layer, and removing the preliminary pixel defining film layer by dry etching such that the upper surface of the preliminary protective layer non-overlapping the photosensitive pattern is exposed.

The preliminary pixel defining film layer P-PDL may be formed into a pixel defining film PDL through process operations which will be described later. The method may include patterning the preliminary pixel defining film layer P-PDL and providing the preliminary pixel defining film layer P-PDL on the first electrodes AE spaced apart from each other on the circuit element layer D-CL. The method may include providing the preliminary pixel defining film layer P-PDL such that the preliminary pixel defining film layer P-PDL covers the preliminary protective layer P-PTL and the exposed upper and side surfaces of the first electrode AE. The preliminary pixel defining film layer P-PDL may be formed of an inorganic material. However, embodiments supported by the present disclosure are not limited thereto.

Referring to FIG. 12E, the method may include forming the photosensitive pattern PR on the preliminary pixel defining film layer P-PDL. Referring to FIGS. 12E and 12F, the photosensitive pattern PR formed on the preliminary pixel defining film layer P-PDL is for forming the pixel defining film PDL formed to correspond to the peripheral region NPXA (see FIG. 7). The method may include defining, by the photosensitive pattern PR formed on the preliminary pixel defining film layer P-PDL, a light-emitting opening OH which corresponds to the light-emitting regions PXA-B, PXA-G, and PXA-R (see FIG. 7). The method may include forming the pixel defining film PDL such that the pixel defining film PDL as disposed corresponds to the peripheral region NPXA (see FIG. 7).

The patterning of the preliminary pixel defining film layer P-PDL to form the pixel defining film PDL having a light-emitting opening OH defined therein may include removing portions of the preliminary pixel defining film layer P-PDL by dry etching ET-D, which may form the pixel defining film PDL having the light-emitting opening OH defined therein. The method may include exposing the upper surface of the preliminary protective layer P-PTL disposed on the first electrode AE by patterning the preliminary pixel defining film layer P-PDL. The upper surface of the preliminary protective layer P-PTL may be exposed by the light-emitting opening OH formed by patterning the preliminary pixel defining film layer P-PDL.

The pixel defining film PDL formed by patterning the preliminary pixel defining film layer P-PDL may overlap at least a portion of the first electrode AE. The pixel defining film PDL may overlap the first electrode AE in a region that does not overlap the light-emitting opening OH. The preliminary protective layer P-PTL may be directly disposed between the pixel defining film PDL and the first electrode AE which overlap each other. The preliminary protective layer P-PTL disposed directly between the pixel defining film PDL and the first electrode AE may be formed into the protective layer PTL (see FIG. 7) through processes which will be described later. In the operation of an embodiment illustrated in FIG. 12F, the upper surface of the preliminary protective layer P-PTL may be exposed by the light-emitting opening OH, and for a portion of the preliminary protective layer P-PTL overlapping the pixel defining film PDL, the preliminary protective layer P-PTL may be disposed directly between the pixel defining film PDL and the second sub-electrode SEL2 to protect the first electrode AE. In one operation of the method of manufacturing the display device illustrated in FIG. 12F, the preliminary protective layer P-PTL may protect the first electrode AE during dry etching ET-D associated with forming the pixel defining film PDL.

FIG. 12G illustrates an example of forming a protective layer. The method may include forming the protective layer PTL by removing the preliminary protective layer P-PTL (see FIG. 12F) exposed by the light-emitting opening OH. The forming of the protective layer PTL may include performing a wet etching of the preliminary protective layer P-PTL. The wet etching may include providing an etching solution on the preliminary protective layer P-PTL (see FIG. 12F) exposed by the light-emitting opening OH, which may remove the preliminary protective layer P-PTL (see FIG. 12F) and expose the upper surface of the second sub-electrode SEL2.

When viewed on a cross section parallel to the third direction axis DR3, an edge of the protective layer PTL formed by removing the preliminary protective layer P-PTL (see FIG. 12F) may be exposed by the light-emitting opening OH. In some aspects, the other edge of the protective layer PTL may be covered with the pixel defining film PDL.

In some aspects, with reference to the protective layer PTL formed by the method of manufacturing the display device according to an embodiment supported by aspects of the present disclosure, the edge exposed by the light-emitting opening OH may be more recessed toward the inside of the pixel defining film PDL than the edge of the pixel defining film PDL exposed by the light-emitting opening OH. That is, based on a wet etching process performed in association with forming the protective layer PTL as described herein, the edge of the protective layer PTL may be formed such that the edge of the protective layer PTL is more recessed toward the inside of the pixel defining film PDL than the edge of the pixel defining film PDL. The edge of the protective layer PTL may overlap the pixel defining film PDL.

Although not illustrated, the method of manufacturing the display device according to an embodiment supported by aspects of the present disclosure may include forming light-emitting elements ED1, ED2, and ED3 (see FIG. 7) by sequentially providing functional layers FL1, FL2, and FL3 (see FIG. 7) and a second electrode CE on the light-emitting opening OH and the pixel defining film PDL. In an embodiment supported by aspects of the present disclosure, the method may include disposing the functional layers FL1, FL2, and FL3 (see FIG. 7) such that the functional layers FL1, FL2, and FL3 cover the edge of the protective layer PTL and are more recessed toward the inside of the pixel defining film PDL than the edge of the pixel defining film PDL.

The method of manufacturing the display device according to an embodiment supported by aspects of the present disclosure includes collectively etching the preliminary first sub-electrode, the preliminary intermediate layer, and the preliminary second sub-electrode in a single process operation to form the first electrode in which the first sub-electrode, the intermediate layer, and the second sub-electrode are stacked, and thus the method exhibits excellent process productivity. In some aspects, by performing collective dry etching in association with forming the first electrode, the method supports high-precision patterning and implementing a high-resolution display device. In some aspects, the first electrode is sufficiently protected during a display device manufacturing process by a protective layer including an amorphous transparent conductive oxide film provided on the first electrode, and the display device may exhibit excellent display quality.

In the display device according to an embodiment supported by aspects of the present disclosure, the first electrode is disposed between two sub-electrodes and includes an intermediate layer containing a tungsten oxide, thereby exhibiting excellent electrical characteristics through improved contact resistance.

In some aspects, in the display device according to an embodiment supported by aspects of the present disclosure, the first electrode has a stacked structure of a first sub-electrode including a reflective metal material, an intermediate layer including a tungsten oxide, and a second sub-electrode including a transparent conductive oxide, and the first electrode may be formed by etching in one process operation of the display device manufacturing process according to an embodiment supported by aspects of the present disclosure, thereby making it possible to implement a display device having high resolution.

Although the above has been described with reference to example embodiments supported by aspects of the present disclosure, those skilled in the art or those of ordinary skill in the art will understand that various modifications and changes can be made to the inventive concept within the scope that does not depart from the spirit and technical field supported by aspects of the present disclosure described in the claims to be described later.

Accordingly, the technical scope supported by aspects of the present disclosure should not be limited to the content described in the detailed description of the specification, but should be determined by the claims described hereinafter.

What is claimed is:

1. A display device comprising:
a circuit element layer;
a pixel defining film disposed on the circuit element layer, wherein a light-emitting opening is defined in the pixel defining film;
a light-emitting element comprising:
a first electrode comprising an upper surface exposed through the light-emitting opening, wherein the first electrode at least partially overlaps the pixel defining film;
a second electrode disposed on the first electrode; and
a functional layer disposed between the first electrode and the second electrode; and
a protective layer disposed between the first electrode overlapping the pixel defining film and the pixel defining film,
wherein the first electrode comprises:
a first sub-electrode comprising a reflective metal material;
a second sub-electrode disposed on the first sub-electrode and comprising a transparent conductive oxide; and
an intermediate layer disposed directly between the first sub-electrode and the second sub-electrode and comprising a tungsten oxide.

2. The display device of claim 1, wherein an edge of the protective layer exposed through the light-emitting opening is more recessed toward an inside of the pixel defining film than an edge of an adjacent pixel defining film.

3. The display device of claim 1, wherein the first sub-electrode comprises aluminum or an aluminum alloy.

4. The display device of claim 1, wherein the second sub-electrode comprises a polycrystalline indium tin oxide (ITO).

5. The display device of claim 1, wherein the protective layer is formed of an amorphous transparent conductive oxide film.

6. The display device of claim 5, wherein the protective layer comprises at least one of indium gallium zinc oxide (IGZO), indium zinc oxide (IZO), or zinc indium tin oxide (Zn-ITO).

7. The display device of claim 1, wherein a thickness of the intermediate layer ranges from about 5 Å to about 30 Å.

8. A display device comprising:
light-emitting regions which are non-overlapping on a plane;
a peripheral region disposed between the light-emitting regions;
a base substrate;
a circuit element layer disposed on the base substrate;
a pixel defining film disposed on the circuit element layer, wherein light-emitting openings defined in the pixel defining film correspond to the light-emitting regions;
a light-emitting element comprising:
a first electrode at least partially overlapping the pixel defining film and disposed on the circuit element layer,
a second electrode facing the first electrode, and
a functional layer disposed between the first electrode and the second electrode; and
a protective layer disposed directly between the first electrode and the pixel defining film, wherein the protective layer corresponds to the peripheral region and is formed of an amorphous transparent conductive oxide film.

9. The display device of claim 8, wherein the first electrode comprises:
a first sub-electrode comprising a reflective metal material;
a second sub-electrode disposed on the first sub-electrode and comprising a transparent conductive oxide; and
an intermediate layer disposed directly between the first sub-electrode and the second sub-electrode and comprising a tungsten oxide.

10. The display device of claim 9, wherein:
the first sub-electrode comprises aluminum or an aluminum alloy; and
the second sub-electrode comprises a polycrystalline indium tin oxide (ITO).

11. The display device of claim 9, wherein:
a thickness of the first sub-electrode ranges from about 600 Å to about 1000 Å;
a thickness of the second sub-electrode ranges from about 20 Å to about 100 Å; and
a thickness of the intermediate layer ranges from about 5 Å to about 30 Å.

12. The display device of claim 9, wherein:
the first electrode, the protective layer, and the pixel defining film overlap each other in the peripheral region; and
the protective layer and the pixel defining film do not overlap the first electrode in the light-emitting regions.

13. The display device of claim 8, wherein the base substrate comprises a silicon substrate.

14. A method for manufacturing a display device, the method comprising:
sequentially providing a preliminary first sub-electrode, a preliminary intermediate layer, a preliminary second sub-electrode, and a preliminary protective layer on a circuit element layer;
patterning the preliminary protective layer by removing a portion of the preliminary protective layer;
forming a first electrode, in which a first sub-electrode, an intermediate layer, and a second sub-electrode are stacked, by etching portions of the preliminary first sub-electrode, the preliminary intermediate layer, and the preliminary second sub-electrode which overlap a region from which the portion of the preliminary protective layer is removed;
providing a preliminary pixel defining film layer on the formed first electrode;
forming a pixel defining film by patterning the preliminary pixel defining film layer, wherein a light-emitting opening is defined in the pixel defining film; and
forming a protective layer by removing a portion of the preliminary protective layer exposed through the light-emitting opening, wherein an edge of the protective layer exposed through the light-emitting opening is more recessed toward an inside of the pixel defining film than an edge of the pixel defining film.

15. The method of claim 14, wherein the patterning of the preliminary protective layer by removing a portion of the preliminary protective layer comprises:
forming a photosensitive pattern on the preliminary protective layer; and
removing a portion of the preliminary protective layer that does not overlap the photosensitive pattern by wet etching the preliminary protective layer, wherein the wet etching comprises providing an etching solution on the preliminary protective layer.

16. The method of claim 14, wherein the forming of the first electrode comprises dry etching the preliminary first sub-electrode, the preliminary intermediate layer, and the preliminary second sub-electrode in a same process step.

17. The method of claim 14, wherein the forming of the pixel defining film comprises:
forming a photosensitive pattern on the preliminary pixel defining film layer; and
removing the preliminary pixel defining film layer by dry etching the preliminary pixel defining film layer such that an upper surface of the preliminary protective layer non-overlapping the photosensitive pattern is exposed.

18. The method of claim 14, wherein the forming of the protective layer comprises removing the portion of the preliminary protective layer exposed through the light-emitting opening by wet etching such that an upper surface of the second sub-electrode is exposed, wherein the wet etching comprises providing an etching solution on the preliminary protective layer.

19. The method of claim 14, wherein:
the preliminary first sub-electrode comprises aluminum or an aluminum alloy;
the preliminary second sub-electrode comprises a polycrystalline indium tin oxide (ITO); and
the preliminary intermediate layer comprises a tungsten oxide.

20. The method of claim 14, wherein the preliminary protective layer comprises an amorphous transparent conductive oxide film.
